(19) United States
(12) Patent Application Publication
(10) Pub. No.: US 2025/0063728 A1
(43) Pub. Date: Feb. 20, 2025

(54) ANTIFUSE-TYPE ONE TIME PROGRAMMING MEMORY AND ASSOCIATED BIAS VOLTAGE CONTROL METHOD

(71) Applicant: eMemory Technology Inc., Hsin-Chu (TW)

(72) Inventors: Lun-Chun CHEN, Hsinchu County (TW); Ping-Lung Ho, Hsinchu County (TW); Chun-Fu Lin, Hsinchu County (TW); Hsin-Ming Chen, Hsinchu County (TW)

(21) Appl. No.: 18/785,387

(22) Filed: Jul. 26, 2024

Related U.S. Application Data
(60) Provisional application No. 63/532,701, filed on Aug. 15, 2023.
(60) Provisional application No. 63/598,558, filed on Nov. 14, 2023.

(51) Int. Cl. H10B 20/25

(52) U.S. Cl. CPC H10B 20/25

(57) ABSTRACT

An antifuse-type one time programming memory includes a first memory cell. The first memory cell includes an antifuse transistor. The antifuse transistor includes a first nanowire, a first gate structure, a first drain/source structure and a second drain/source structure. The first nanowire is surrounded by the first gate structure. The first gate structure includes a first spacer, a second spacer, a first gate dielectric layer and a first gate layer. The first drain/source structure is electrically contacted with the first terminal of the first nanowire. The second drain/source structure is electrically contacted with the second terminal of the first nanowire.

This application claims the benefit of U.S. provisional application Ser. No. 63/532,701, filed Aug. 15, 2023, and the benefit of U.S. provisional application Ser. No. 63/598,558, filed Nov. 14, 2023, the subject matters of which are incorporated herein by references.

### FIELD OF THE INVENTION

The present invention relates to a non-volatile memory and a control method, and more particularly to an antifuse-type one time programming memory and an associated bias voltage control method.

### BACKGROUND OF THE INVENTION

As is well known, an antifuse-type one time programming memory (also referred as an antifuse-type OTP memory) is one of the non-volatile memories. Before the memory cell of the antifuse-type OTP memory is programmed, the memory cell is in a high-resistance storage state. After the memory cell of the antifuse-type OTP memory is programmed, the memory cell is in a low-resistance storage state. In addition, after the memory cell of the antifuse-type OTP memory is programmed, the stored data in the memory cell cannot be changed.

Generally, the antifuse-type OTP memory comprises a peripheral circuit and an array structure. The peripheral circuit and the array structure are fabricated on a semiconductor substrate. The array structure comprises plural memory cells. Each of the plural memory cells comprises a storage transistor. The peripheral circuit comprises a control circuit and a power circuit. Under control of the control circuit, the power circuit provides proper bias voltages to the selected memory cell of the array structure. Consequently, a program action or a read action is selectively performed on the selected memory cell. For example, the power circuit is a charge pump.

With the continuous evolution of semiconductor manufacturing processes, transistors have been gradually developed from the early planar transistors to fin field-effect transistors (Fin-FETs). In a more advanced process, a gate-all-around (GAA) transistor has been produced. The size of the GAA transistor is smaller. Moreover, a channel region of the GAA transistor is surrounded by a gate electrode of the GAA transistor. As known, the GAA transistor has good gate control capability and low source/drain leakage current. As a consequently, traditional transistors are gradually replaced by the GAA transistors.

### SUMMARY OF THE INVENTION

An embodiment of the present invention provides an antifuse-type one time programming memory. The antifuse-type one time programming memory includes a first memory cell. The first memory cell includes: a P-type semiconductor substrate; a P-type well region formed in a surface of the P-type semiconductor substrate; an N-type region formed in the P-type semiconductor substrate and located under the P-type well region, wherein a region of the P-type semiconductor substrate underlying the N-type region and the P-type well region are separated from each other through the N-type region, and the P-type well region is formed as an isolated P-type well region; a first nanowire; a first gate structure comprising a first spacer, a second spacer, a first gate dielectric layer and a first gate layer, wherein the first gate dielectric layer surrounds a central region of the first nanowire, the first gate layer covers the first gate dielectric layer, the first gate layer is electrically connected with a first word line, a first terminal of the first nanowire is surrounded by the first spacer, a second terminal of the first nanowire is surrounded by the second spacer, and the first spacer and the second spacer are located over the P-type well region; a first drain/source structure located over the P-type well region and electrically contacted with the first terminal of the first nanowire, wherein the first drain/source structure is electrically connected with a first bit line; a second drain/source structure located over the P-type well region and electrically contacted with the second terminal of the first nanowire, wherein the first nanowire, the first gate structure, the first drain/source structure and the second drain/source structure are collaboratively formed as a first select transistor; a second nanowire; a second gate structure comprising a third spacer, a fourth spacer, a second gate dielectric layer and a second gate layer, wherein the second gate dielectric layer surrounds a central region of the second nanowire, the second gate layer covers the second gate dielectric layer, the second gate layer is electrically connected with a first antifuse control line, a first terminal of the second nanowire is surrounded by the third spacer, a second terminal of the second nanowire is surrounded by the fourth spacer, and the third spacer and the fourth spacer are located over the P-type well region; a third drain/source structure located over the P-type well region and electrically contacted with the first terminal of the second nanowire, wherein the third drain/source structure is coupled to the second drain/source structure; a fourth drain/source structure located over the P-type well region and electrically contacted with the second terminal of the second nanowire, wherein the second nanowire, the second gate structure, the third drain/source structure and the fourth drain/source structure are collaboratively formed as a first antifuse transistor; wherein when a program action is performed, the P-type well region receives a negative program voltage, the N-type region receives a first voltage, and the P-type semiconductor substrate receives a second voltage, a region between the P-type well region and the N-type region is in a reverse bias condition, and a region between the P-type semiconductor substrate and the N-type region is in the reverse bias condition or a zero bias condition, wherein the first voltage is higher than or equal to a ground voltage, the second voltage is higher than or equal to the negative program voltage, and the second voltage is lower than or equal to the first voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic perspective view illustrating the structure of a GAA transistor according to an embodiment of the present invention;

FIG. 1B is a schematic cross-sectional view illustrating the GAA transistor shown in FIG. 1A and taken along the line a-b;

FIG. 1C is a schematic top view illustrating the GAA transistor shown in FIG. 1A;

FIG. 2A is a schematic perspective view illustrating the structure of two GAA transistors according to an embodiment of the present invention;

FIG. 2B is a schematic top view illustrating the structure of the two GAA transistors shown in FIG. 2A;

FIG. 3A is a schematic top view illustrating the array structure of an antifuse-type OTP memory according to a first embodiment of the present invention;

FIG. 3B is a schematic cross-sectional view illustrating the array structure shown in FIG. 3A and taken along the line cd;

FIG. 3C is a schematic cross-sectional view illustrating the array structure shown in FIG. 3A and taken along the line ef;

FIG. 3D is a table illustrating the bias voltages for performing a program action and a read action on the antifuse-type OTP memory of the first embodiment;

FIG. 4A is a schematic top view illustrating the array structure of an antifuse-type OTP memory according to a second embodiment of the present invention;

FIG. 4B is a schematic cross-sectional view illustrating the array structure shown in FIG. 4A and taken along the line gh;

FIG. 4C is a schematic cross-sectional view illustrating the array structure shown in FIG. 4A and taken along the line ij;

FIG. 4D is a table illustrating the bias voltages for performing a program action and a read action on the antifuse-type OTP memory of the second embodiment;

FIG. 5A is a schematic top view illustrating the array structure of an antifuse-type OTP memory according to a third embodiment of the present invention;

FIG. 5B is a table illustrating the bias voltages for performing a program action and a read action on the antifuse-type OTP memory of the third embodiment;

FIG. 6A is a schematic top view illustrating the array structure of an antifuse-type OTP memory according to a fourth embodiment of the present invention; and

FIG. 6B is a table illustrating the bias voltages for performing a program action and a read action on the antifuse-type OTP memory of the fourth embodiment.

### DETAILED DESCRIPTION OF PREFERRED EMBODIMENTS

The present invention provides an antifuse-type one time programming (OTP) memory and an associated bias voltage control method. The transistors of the antifuse-type OTP memory are GAA transistors. For example, the transistors of the peripheral circuit and the array structure of the antifuse-type OTP memory are GAA transistors. In addition, the GAA transistors are fabricated on a semiconductor substrate.

Generally, the size of the GAA transistor is small. In addition, the GAA transistor is capable of withstanding a low voltage. For example, the GAA transistor is capable of withstanding 2.5V. Consequently, the process of manufacturing the antifuse-type OTP memory with GAA transistors is usually suffered from some drawbacks.

For example, when the program action of the antifuse-type OTP memory is performed, a higher voltage difference (e.g., 5V) is required to be transmitted to the storage transistor of the selected memory cell. In addition, the storage transistor is a GAA transistor. When the program action is performed, the power circuit provides the higher voltage difference to the two sides of the gate dielectric layer of the storage transistor. If the voltage difference is higher than the voltage stress that the gate dielectric layer ca withstand, the gate dielectric layer is ruptured. Consequently, the memory cell is in the low-resistance storage state. The power circuit is equipped with a charge pump to receive a supply voltage V_{DD} and generate a 5V output voltage for the program action. For example, the supply voltage V_{DD} is higher than or equal to 0.4V, and the supply voltage V_{DD} is lower than or equal to 1.6V.

Generally, the GAA transistor cannot withstand the excessive voltage stress. If a single power circuit is provided to generate the 5V output voltage directly, the GAA transistor in the charge pump will not be able to withstand this voltage stress, causing the charge pump to be damaged and unable to operate normally. Consequently, it is necessary to use plural power circuits in the OTP memory to generate plural voltages and combine plural voltages to generate a large voltage difference to perform the program action.

For meeting the above requirements, the present invention provides an antifuse-type OTP memory and an associated bias voltage control method. The antifuse-type OTP memory comprises plural power circuits. One power circuit provides a positive voltage. Another power circuit provides a negative voltage. The magnitude of the voltage provided by each power circuit is smaller than the withstand voltage of the GAA transistor. Consequently, the power circuit can be operated normally. Furthermore, the positive voltage and the negative voltage respectively provided by the two power circuits are combined as a program voltage with a large voltage difference, and the program voltage is used for the program action.

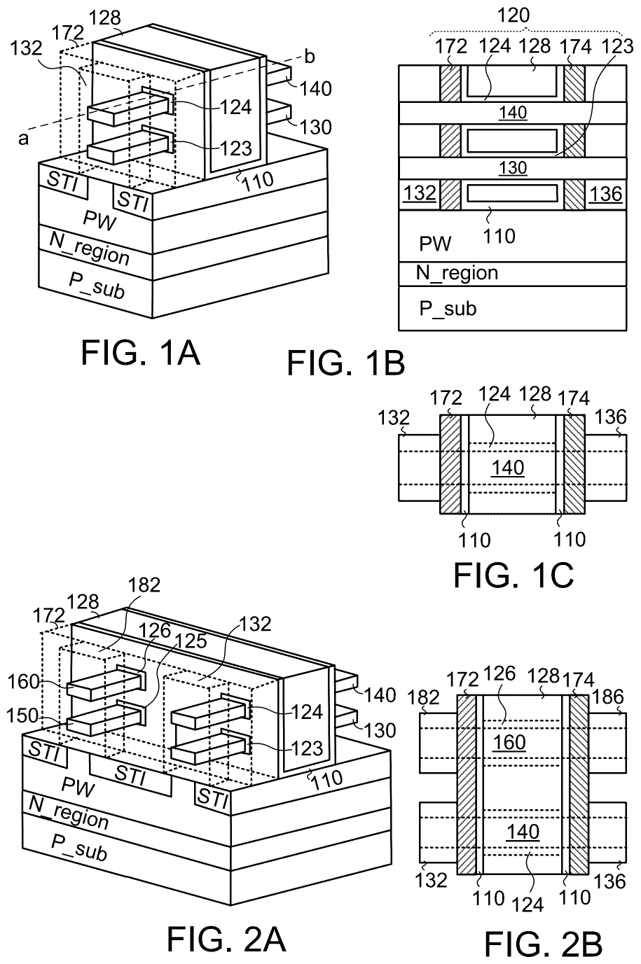

FIG. 1A is a schematic perspective view illustrating the structure of a GAA transistor according to an embodiment of the present invention. FIG. 1B is a schematic cross-sectional view illustrating the GAA transistor shown in FIG. 1A and taken along the line a-b. FIG. 1C is a schematic top view illustrating the GAA transistor shown in FIG. 1A. The GAA transistor and associated components are formed as a memory cell. In addition, plural memory cells are formed as an array structure of the OPT memory.

As shown in FIG. 1A and FIG. 1B, an isolation structure STI is formed on a surface of a P-well region PW in a P-type semiconductor substrate P_sub. For example, the isolation structure STI is a shallow trench isolation (STI) structure. A gate structure 120 is formed over the surface of the P-well region PW and the surface of the isolation structure STI. Two nanowires 130 and 140 are penetrated through the gate structure 120. That is, the nanowires 130 and 140 are surrounded and supported by the gate structure 120. For example, the nanowires 130 and 140 are rectangular nanowires or cylindrical nanowires. In an embodiment, two drain/source structures 132 and 136 are electrically contacted with the nanowires 130 and 140, and the nanowires 130 and 140 are penetrated through the two drain/source structures 132 and 136. Alternatively, the nanowires 130 and 140 are not penetrated through the two drain/source structures 132 and 136, but the first terminals and the second terminals of the nanowires 130 and 140 are electrically contacted with the drain/source structures 132 and 136. The two drain/source structures 132 and 136, the gate structure 120 and the nanowires 130 and 140 are collaboratively formed as a GAA transistor.

It is noted that the number of nanowires in the GAA transistor is not restricted. For example, in another embodiment, the GAA transistor comprises one nanowire or more than two nanowires. Furthermore, as shown in FIGS. 1A and 1B, an N-type region N_region is formed in the P-type semiconductor substrate P_sub and located under the P-well region PW. For example, the N-type region N_region is a deep N-Well (DNW) region or an N-buried layer (NBL). The P-type semiconductor substrate P_sub and the P-well region PW are separated from each other through the N-type region N_region. Consequently, the P-type semiconductor substrate P_sub and the P-well region PW are not contacted with each other. The P-well region PW is formed as an isolated P-well region.

As shown in FIG. 1B, the gate structure 120 is located over the P-well region PW and the isolation structure STI. The gate structure 120 comprises two spacers 172 and 174, three gate dielectric layers 110, 123 and 124, and a gate layer 128. The two spacers 172 and 174 are located over the P-well region PW. The two spacers 172 and 174 and the gate dielectric layers 110, 123 and 124 are electrical insulators. The gate dielectric layer 110 is contacted with the surface of the P-well region PW and the surface of the isolation structure STI. The gate dielectric layer 123 surrounds the central region of the nanowire 130. The gate dielectric layer 124 surrounds the central region of the nanowire 140. In addition, the gate dielectric layer 110 is contacted with the first side surfaces of the spacers 172 and 174. The gate layer 128 covers the gate dielectric layers 110, 123 and 124. The two spacers 172 and 174 are formed over the surface of the P-well region PW and the surface of the isolation structure STI. The first terminals of the nanowires 130 and 140 are surrounded by the spacer 172 and supported by the spacer 172. The second terminals of the nanowires 130 and 140 are surrounded by the spacer 174 and supported by the spacer 174. The nanowires 130 and 140 that are surrounded by the gate structure 120 are served as a nanowire channel region of a GAA transistor.

Furthermore, two drain/source structures 132 and 136 are formed over the surface of the P-well region PW and the surface of the isolation structure STI. The drain/source structure 132 is contacted with the second surface of spacer 172. The drain/source structure 136 is contacted with the second surface of spacer 174. The drain/source structure 132 is electrically contacted with the first terminals of the nanowires 130 and 140. The drain/source structure 136 is electrically contacted with the second terminals of the nanowires 130 and 140. In an embodiment, the drain/source structure 132, the drain/source structure 136 and the nanowires 130 and 140 have the same dopant type. For example, the drain/source structure 132, the drain/source structure 136 and the nanowires 130 and 140 are n-type or p-type doped structures.

As shown in FIG. 1B, the GAA transistor comprises the gate structure 120, the nanowire 130, the nanowire 134, the drain/source structure 132 and the drain/source structure 136. The gate structure 120 at least comprises the two spacers 172 and 174, the gate dielectric layers 123 and 124, and the gate layer 128.

FIG. 2A is a schematic perspective view illustrating the structure of two GAA transistors according to an embodiment of the present invention. FIG. 2B is a schematic top view illustrating the structure of the two GAA transistors shown in FIG. 2A. In comparison with FIGS. 1A and 1C, an additional GAA transistor is shown in FIGS. 2A and 2B. The structures of the two GAA transistors are identical. In addition, the spacers 172 and 174 and the gate layer 128 are shared by the two GAA transistors. For succinctness, only the structure of the additional GAA transistor will be described as follows.

The additional GAA transistor comprises two drain/source structures 182 and 186, a gate structure, and two nanowires 150 and 160. The gate structure of the additional GAA transistor comprises the two spacers 172 and 174, two gate dielectric layers 125 and 126, and the gate layer 128. The gate dielectric layer 125 surrounds the central region of the nanowire 150. The gate dielectric layer 126 surrounds the central region of the nanowire 160. Moreover, the gate layer 128 covers the gate dielectric layers 125 and 126. The first terminals of the nanowires 150 and 160 are surrounded by the spacer 172 and supported by the spacer 172. The second terminals of the nanowires 150 and 160 are surrounded by the spacer 174 and supported by the spacer 174. The drain/source structure 182 is electrically contacted with the first terminals of the nanowires 150 and 160. The drain/source structure 186 is electrically contacted with the second terminals of the nanowires 150 and 160.

As shown in FIG. 2A, two GAA transistors are constructed over the P-type semiconductor substrate P_sub. The drain/source structure 132 and the drain/source structure 182 are not electrically connected with each other. The drain/source structure 136 and the drain/source structure 188 are not electrically connected with each other. In addition, the spacers 172 and 174 and the gate layer 128 are shared by the two GAA transistors. It is noted that numerous modifications and alterations may be made while retaining the teachings of the invention. For example, in some other embodiments, more than two GAA transistors are constructed over the P-type semiconductor substrate P_sub, and the spacers 172 and 174 and the gate layer 128 are shared by the two GAA transistors.

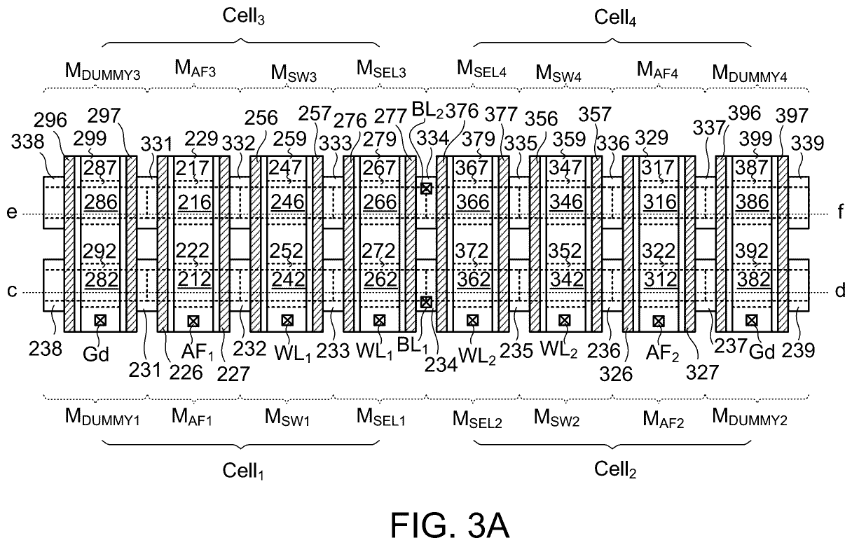

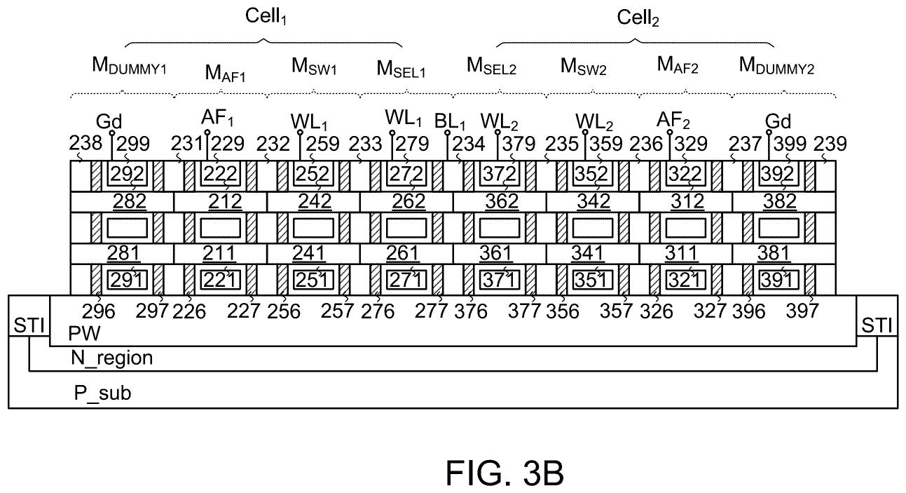

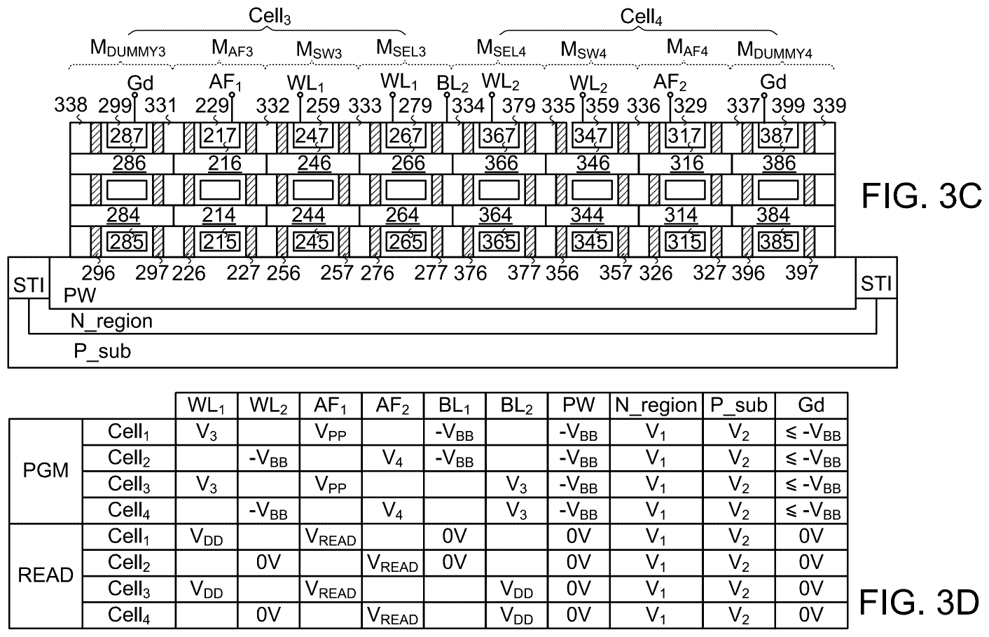

FIG. 3A is a schematic top view illustrating the array structure of an antifuse-type OTP memory according to a first embodiment of the present invention. FIG. 3B is a schematic cross-sectional view illustrating the array structure shown in FIG. 3A and taken along the line cd. FIG. 3C is a schematic cross-sectional view illustrating the array structure shown in FIG. 3A and taken along the line ef.

The array structure comprises four memory cells Cell₁˜Cell₄ in a 2×2 array. The structures of the four memory cells Cell₁˜Cell₄ are similar. Moreover, the array structure is constructed over a P-well region PW in a P-type semiconductor substrate P_sub. In addition, an N-type region N_region is formed in the P-type semiconductor substrate P_sub and located under the P-well region PW. For example, the N-type region N_region is a deep N-Well (DNW) region or an N-buried layer (NBL). The P-type semiconductor substrate P_sub and the P-well region PW are separated from each other through the N-type region N_region.

The array structure is at least connected with bit lines BL₁ and BL₂, word lines WL₁ and WL₂ and antifuse control lines AF₁ and AF₂. Each of the memory cells Cell₁˜Cell₄ in the array structure comprises at least three GAA transistors. The structure of each GAA transistor is the identical to the structure of the GAA transistor shown in FIG. 1A.

The first memory cell Cell₁ comprises a select transistor M_{SEL1}, a switching transistor M_{SW1} and an antifuse transistor M_{AF1}. The select transistor M_{SEL1} is coupled to the antifuse transistor M_{AF1} through the switching transistor M_{SW1}. The antifuse transistor M_{AF1} is used as a storage transistor.

The select transistor M_{SEL1} comprises a drain/source structure 233, a drain/source structure 234, a gate structure, a nanowire 261 and a nanowire 262. The gate structure comprises two spacers 276 and 277, two gate dielectric layers 271 and 272, and a gate layer 279. The gate dielectric layer 271 surrounds the central region of the nanowire 261. The gate dielectric layer 272 surrounds the central region of the nanowire 262. The gate layer 279 surrounds the gate dielectric layers 271 and 272. The first terminals of the nanowires 261 and 262 are surrounded by the spacer 276. The second terminals of the nanowires 261 and 262 are surrounded by the spacer 277. The nanowires 261 and 262 that are surrounded by the gate structure are served as a nanowire channel region of the select transistor M_{SEL1}. The drain/source structure 233 and the drain/source structure 234 are respectively located beside the two sides of the gate structure. The drain/source structure 233 is electrically contacted with the first terminals of the nanowires 261 and 262. The drain/source structure 234 is electrically contacted with the second terminals of the nanowires 261 and 262. The drain/source structure 234 is electrically contacted with the bit line BL₁. The gate layer 279 is electrically connected with the word line WL₁.

The switching transistor M_{SW1} comprises the drain/source structure 232, a drain/source structure 233, a gate structure, a nanowire 241 and a nanowire 242. The gate structure comprises two spacers 256 and 257, two gate dielectric layers 251 and 252, and a gate layer 259. The gate dielectric layer 251 surrounds the central region of the nanowire 241. The gate dielectric layer 252 surrounds the central region of the nanowire 242. The gate layer 259 surrounds the gate dielectric layers 251 and 252. The first terminals of the nanowires 241 and 242 are surrounded by the spacer 256. The second terminals of the nanowires 241 and 242 are surrounded by the spacer 257. The nanowires 241 and 242 that are surrounded by the gate structure are served as a nanowire channel region of the switching transistor M_{SW1}. The drain/source structure 232 and the drain/source structure 233 are respectively located beside the two sides of the gate structure. The drain/source structure 232 is electrically contacted with the first terminals of the nanowires 241 and 242. The drain/source structure 233 is electrically contacted with the second terminals of the nanowires 241 and 242. The gate layer 259 is electrically connected with the word line WL₁.

The antifuse transistor M_{AF1} comprises the drain/source structure 231, a drain/source structure 232, a gate structure, a nanowire 211 and a nanowire 212. The gate structure comprises two spacers 226 and 227, two gate dielectric layers 221 and 222, and a gate layer 229. The gate dielectric layer 221 surrounds the central region of the nanowire 211. The gate dielectric layer 222 surrounds the central region of the nanowire 212. The gate layer 229 surrounds the gate dielectric layers 221 and 222. The first terminals of the nanowires 211 and 212 are surrounded by the spacer 226. The second terminals of the nanowires 211 and 212 are surrounded by the spacer 227. The nanowires 211 and 212 that are surrounded by the gate structure are served as a nanowire channel region of the antifuse transistor M_{AF1}. The drain/source structure 231 and the drain/source structure 232 are respectively located beside the two sides of the gate structure. The drain/source structure 231 is electrically contacted with the first terminals of the nanowires 211 and 212. The drain/source structure 232 is electrically contacted with the second terminals of the nanowires 211 and 212. The gate layer 229 is electrically connected with the antifuse control line AF₁.

In the first memory cell Cell₁, the drain/source structure 233 is shared by the select transistor M_{SEL1} and the switching transistor M_{SW1}, and the drain/source structure 232 is shared by the switching transistor M_{SW1} and the antifuse transistor M_{AF1}. The drain/source structure 233 is coupled to the drain/source structure 232 through the switching transistor M_{SW1}. In addition, the drain/source structures 231, 232 and 233 and the nanowires 211, 212, 241, 242, 261 and 262 of the first memory cell Cell₁ have the same dopant type. For example, the drain/source structures 231, 232 and 233 and the nanowires 211, 212, 241, 242, 261 and 262 are n-type or p-type doped structures.

The second memory cell Cell₂ comprises a select transistor M_{SEL2}, a switching transistor M_{SW2} and an antifuse transistor M_{AF2}. The antifuse transistor M_{AF2} is used as a storage transistor.

The select transistor M_{SEL2} comprises a drain/source structure 234, a drain/source structure 235, a gate structure, a nanowire 361 and a nanowire 362. The gate structure comprises two spacers 376 and 377, two gate dielectric layers 371 and 372, and a gate layer 379. The drain/source structure 234 is electrically contacted with the bit line BL₁. The gate layer 379 is electrically connected with the word line WL₂.

The switching transistor M_{SW2} comprises a drain/source structure 235, the drain/source structure 236, a gate structure, a nanowire 341 and a nanowire 342. The gate structure comprises two spacers 356 and 357, two gate dielectric layers 351 and 352, and a gate layer 359. The gate layer 359 is electrically connected with the word line WL₂.

The antifuse transistor M_{AF2} comprises a drain/source structure 236, the drain/source structure 237, a gate structure, a nanowire 311 and a nanowire 312. The gate structure comprises two spacers 326 and 327, two gate dielectric layers 321 and 322, and a gate layer 329. The gate layer 329 is electrically connected with the antifuse control line AF₂.

In the second memory cell Cell₂, the drain/source structure 235 is shared by the select transistor M_{SEL2} and the switching transistor M_{SW2}, and the drain/source structure 236 is shared by the switching transistor M_{SW2} and the antifuse transistor M_{AF2}. In addition, the drain/source structures 235, 236 and 237 and the nanowires 311, 312, 341, 342, 361 and 362 of the second memory cell Cell₂ have the same dopant type.

The third memory cell Cell₃ comprises a select transistor M_{SEL3}, a switching transistor M_{SW3} and an antifuse transistor M_{AF3}. The antifuse transistor M_{AF3} is used as a storage transistor.

The select transistor M_{SEL3} comprises a drain/source structure 333, a drain/source structure 334, a gate structure, a nanowire 264 and a nanowire 266. The gate structure comprises the two spacers 276 and 277, two gate dielectric layers 265 and 267, and the gate layer 279. The drain/source structure 334 is electrically contacted with the bit line BL₂. The gate layer 279 is electrically connected with the word line WL₁. In addition, the spacers 276 and 277 and the gate layer 279 are shared by the select transistor M_{SEL3} of the third memory cell Cell₃ and the select transistor M_{SEL1} of the first memory cell Cell₁.

The switching transistor M_{SW3} comprises a drain/source structure 332, a drain/source structure 333, a gate structure, a nanowire 244 and a nanowire 246. The gate structure comprises two spacers 256 and 257, two gate dielectric layers 245 and 247, and a gate layer 259. The gate layer 259 is electrically connected with the word line WL₁. In addition, the spacers 256 and 257 and the gate layer 259 are shared by the switching transistor M_{SW3} of the third memory cell Cell₃ and the switching transistor M_{SW1} of the first memory cell Cell₁.

The antifuse transistor M_{AF3} comprises a drain/source structure 331, a drain/source structure 332, a gate structure, a nanowire 214 and a nanowire 216. The gate structure comprises two spacers 226 and 227, two gate dielectric layers 215 and 217, and a gate layer 229. The gate layer 229 is electrically connected with the antifuse control line AF₁. In addition, the spacers 226 and 227 and the gate layer 229 are shared by the antifuse transistor M_{AF3} of the third memory cell Cell₃ and the antifuse transistor M_{AF1} of the first memory cell Cell₁.

In the third memory cell Cell₃, the drain/source structure 333 is shared by the select transistor M_{SEL3} and the switching transistor M_{SW3}, and the drain/source structure 332 is shared by the switching transistor M_{SW3} and the antifuse transistor M_{AF3}. In addition, the drain/source structures 331, 332 and 333 and the nanowires 214, 216, 244, 246, 264 and 266 of the third memory cell Cell₃ have the same dopant type.

The fourth memory cell Cell₄ comprises a select transistor M_{SEL4}, a switching transistor M_{SW4} and an antifuse transistor M_{AF4}. The antifuse transistor M_{AF4} is used as a storage transistor.

The select transistor M_{SEL4} comprises a drain/source structure 334, a drain/source structure 335, a gate structure, a nanowire 364 and a nanowire 366. The gate structure comprises the two spacers 376 and 377, two gate dielectric layers 365 and 367, and the gate layer 379. The drain/source structure 334 is electrically contacted with the bit line BL₂. The gate layer 379 is electrically connected with the word line WL₂. In addition, the spacers 376 and 377 and the gate layer 379 are shared by the select transistor M_{SEL4} of the fourth memory cell Cell₄ and the select transistor M_{SEL2} of the second memory cell Cell₂.

The switching transistor M_{SW4} comprises a drain/source structure 335, the drain/source structure 336, a gate structure, a nanowire 344 and a nanowire 346. The gate structure comprises two spacers 356 and 357, two gate dielectric layers 345 and 347, and a gate layer 359. The gate layer 359 is electrically connected with the word line WL₂. In addition, the spacers 356 and 357 and the gate layer 359 are shared by the switching transistor M_{SW4} of the fourth memory cell Cell₄ and the switching transistor M_{SW2} of the second memory cell Cell₂.

The antifuse transistor M_{AF4} comprises a drain/source structure 336, the drain/source structure 337, a gate structure, a nanowire 314 and a nanowire 316. The gate structure comprises two spacers 326 and 327, two gate dielectric layers 315 and 317, and a gate layer 329. The gate layer 329 is electrically connected with the antifuse control line AF₂. In addition, the spacers 326 and 327 and the gate layer 329 are shared by the antifuse transistor M_{AF4} of the fourth memory cell Cell₄ and the antifuse transistor M_{AF2} of the second memory cell Cell₂.

In the fourth memory cell Cell₄, the drain/source structure 335 is shared by the select transistor M_{SEL4} and the switching transistor M_{SW4}, and the drain/source structure 336 is shared by the switching transistor M_{SW4} and the antifuse transistor M_{AF4}. In addition, the drain/source structures 335, 336 and 337 and the nanowires 314, 316, 344, 346, 364 and 366 of the fourth memory cell Cell₄ have the same dopant type.

In order to prevent the generation of a larger leakage current, the memory cells in the array structure of the antifuse-type OTP memory further comprises dummy transistors. For example, as shown in FIGS. 3A, 3B and 3C, the four memory cells Cell₁˜Cell₄ comprise respective dummy transistors M_{DUMMY1}˜M_{DUMMY4}.

In the first memory cell Cell₁, the dummy transistor M_{DUMMY1} comprises a drain/source structure 238, a drain/source structure 231, a gate structure, a nanowire 281 and a nanowire 282. The gate structure comprises two spacers 296 and 297, two gate dielectric layers 291 and 292, and a gate layer 299.

In the second memory cell Cell₂, the dummy transistor M_{DUMMY2} comprises a drain/source structure 237, a drain/source structure 239, a gate structure, a nanowire 381 and a nanowire 382. The gate structure comprises two spacers 396 and 397, two gate dielectric layers 391 and 392, and a gate layer 399.

In the third memory cell Cell₃, the dummy transistor M_{DUMMY3} comprises a drain/source structure 338, a drain/source structure 331, a gate structure, a nanowire 284 and a nanowire 286. The gate structure comprises two spacers 296 and 297, two gate dielectric layers 285 and 287, and the gate layer 299.

In the fourth memory cell Cell₄, the dummy transistor M_{DUMMY4} comprises a drain/source structure 337, a drain/source structure 339, a gate structure, a nanowire 384 and a nanowire 386. The gate structure comprises two spacers 396 and 397, two gate dielectric layers 385 and 387, and the gate layer 399. The gate layers 229 and 239 of the four dummy transistors M_{DUMMY1}˜M_{DUMMY4} are connected with a dummy gate control line Gd. In addition, the drain/source structures 238, 239, 338 and 339 of the four dummy transistors M_{DUMMY1}˜M_{DUMMY4} are in a floating state.

FIG. 3D is a table illustrating the bias voltages for performing a program action and a read action on the antifuse-type OTP memory of the first embodiment.

The processes and bias voltages for performing the program action (PGM) and the read action (READ) will be described as follows. For illustration, the first memory cell Cell₁ is a selected memory cell, and the other memory cells Cell₂-Cell₄ are unselected memory cells.

When the array structure is subjected to the program action (PGM), the array structure receives a negative program voltage (−V_{BB}). For preventing from the influence of the negative program voltage (−V_{BB}) on the peripheral circuit of the antifuse-type OTP memory, the array structure is constructed over the P-well region PW, and the P-type semiconductor substrate P_sub and the P-well region PW are separated from each other through the N-type region N_region. Consequently, the P-well region PW is an isolated P-well region.

Moreover, when the program action (PGM) is performed, the P-well region PW receives the negative program voltage (−V_{BB}), the N-type region N_region receives a first voltage V₁, and the P-type semiconductor substrate P_sub receives a second voltage V₂. The negative program voltage (−V_{BB}) is lower than or equal to −1V, and the negative program voltage (−V_{BB}) is higher than or equal to −2.5V. The first voltage V₁ is higher than or equal to 0V, and the first voltage V₁ is lower than or equal to 1.6V. Consequently, the region between the N-type region N_region and the P-well region PW is in a reverse bias condition. Moreover, the second voltage V₂ is higher than or equal to the negative program voltage (−V_{BB}), and the second voltage V₂ is lower than or equal to the first voltage V₁. Consequently, the region between the N-type region N_region and the P-type semiconductor substrate P_sub is in the reverse bias condition, or there is no voltage difference between the N-type region N_region and the P-type semiconductor substrate P_sub (i.e., in a zero bias condition).

Please refer to FIG. 3D again. When the program action (PGM) is performed, the word line WL₁ receives a third voltage V₃, and the word line WL₂ receives the negative program voltage (−V_{BB}). Consequently, the word line WL₁ is a selected word line, and the word line WL₂ is an unselected word line. The third voltage V₃ may be regarded as an on voltage. The third voltage V₃ is higher than or equal to −1V, and the first voltage V₁ is lower than or equal to the supply voltage V_{DD}. In addition, the negative program voltage (−V_{BB}) may be regarded as an off voltage.

The bit line BL₁ receives the negative program voltage (−V_{BB}), and the bit line BL₂ receives the third voltage V₃. The antifuse control line AF₁ receives a positive program voltage V_{PP}, and the antifuse control line AF₂ receives a fourth voltage V₄. The positive program voltage V_{PP} is higher than or equal to 1V, and the positive program voltage V_{PP} is lower than or equal to 2.5V. The fourth voltage V₄ is higher than or equal to the negative program voltage (−V_{BB}), and the fourth voltage V₄ is lower than or equal to 0V.

In the first memory cell Cell₁ (i.e., the selected memory cell) of the array structure, the word line WL₁ receives the third voltage V₃. Consequently, the select transistor M_{SEL1} and the switching transistor M_{SW1} are turned on. The negative program voltage (−V_{BB}) is transmitted from the bit line BL₁ to the antifuse transistor M_{AF1} through the select transistor M_{SEL1} and the switching transistor M_{SW1}. Since the antifuse control line AF₁ receives the positive program voltage V_{PP}, the total voltage stress withstood by the two sides of the gate dielectric layers 221 and 222 of the antifuse transistor M_{AF1} is the total program voltage. That is, the total program voltage is approximately equal to the positive program voltage V_{PP} minus the negative program voltage (−V_{BB}), i.e., V_{PP}+V_{BB}. Consequently, one of the gate dielectric layers 221 and 222 is ruptured. Under this circumstance, the storage state of the first memory cell Cell₁ is changed from an unruptured state to a ruptured state.

In the second memory cell Cell₂ (i.e., the unselected memory cell) of the array structure, the word line WL₂ receives the negative program voltage (i.e., the off voltage). Consequently, the select transistor M_{SEL2} and the switching transistor M_{SW2} are turned off. Since no voltage stress is applied to the two sides of the gate dielectric layers 321 and 322 of the antifuse transistor M_{AF2}, both of the gate dielectric layers 321 and 322 are not ruptured. Under this circumstance, the storage state of the second memory cell Cell₂ is maintained in the unruptured state.

In the third memory cell Cell₃ (i.e., the unselected memory cell) of the array structure, the word line WL₁ receives the third voltage V₃, and the bit line BL₂ receives the third voltage V₃. Consequently, the select transistor M_{SEL3} and the switching transistor M_{SW3} are turned off. Since no voltage stress is applied to the two sides of the gate dielectric layers 215 and 217 of the antifuse transistor M_{AF3}, both of the gate dielectric layers 215 and 217 are not ruptured. Under this circumstance, the storage state of the third memory cell Cell₃ is maintained in the unruptured state.

In the fourth memory cell Cell₄ (i.e., the unselected memory cell) of the array structure, the word line WL₂ receives the negative program voltage (−V_{BB}), and the bit line BL₂ receives the third voltage V₃. Consequently, the select transistor M_{SEL4} and the switching transistor M_{SW4} are turned off. Since no voltage stress is applied to the two sides of the gate dielectric layers 315 and 317 of the antifuse transistor M_{AF4}, both of the gate dielectric layers 315 and 317 are not ruptured. Under this circumstance, the storage state of the fourth memory cell Cell₄ is maintained in the unruptured state.

Moreover, when the program action (PGM) is performed, the voltage received by the gate control line Gd is lower than or equal to the negative program voltage (−V_{BB}). Since the dummy transistors M_{DUMMY1}˜M_{DUMMY4} are ensured to be turned off, no leakage current will be generated.

When the array structure is subjected to the read action (READ), the P-well region PW receives the ground voltage (0V), the N-type region N_region receives the first voltage V₁, and the P-type semiconductor substrate P_sub receives the second voltage V₂. Consequently, Consequently, the region between the N-type region N_region and the P-well region PW is in a reverse bias condition, or there is no voltage difference between the N-type region N_region and the P-well region PW (i.e., in a zero bias condition). Similarly, the region between the N-type region N_region and the P-type semiconductor substrate P_sub is in the reverse bias condition, or there is no voltage difference between the N-type region N_region and the P-type semiconductor substrate P_sub (i.e., in the zero bias condition).

Please refer to FIG. 3D again. When the read action (READ) is performed, the word line WL₁ receives the supply voltage V_{DD}, and the word line WL₂ receives the ground voltage (0V). Consequently, the word line WL₁ is the selected word line, and the word line WL₂ is the unselected word line. The supply voltage V_{DD} may be regarded as an on voltage. In addition, the ground voltage (0V) may be regarded as an off voltage.

The bit line BL₁ receives the ground voltage (0V), and the bit line BL₂ receives the supply voltage V_{DD}. The antifuse control line AF₁ receives a read voltage VREAD, and the antifuse control line AF₂ receives the read voltage VREAD. The read voltage VREAD is higher than or equal to 0.4V, and the read voltage VREAD is lower than or equal to 1.6V.

In the first memory cell Cell₁ (i.e., the selected memory cell) of the array structure, the word line WL₁ receives the supply voltage V_{DD}. Consequently, the select transistor M_{SEL1} and the switching transistor M_{SW1} are turned on. A read current is generated in the region between the antifuse transistor M_{AF1} and the bit line BL₁. The magnitude of the read current is related to the storage state of the first memory cell Cell₁. For example, if the first memory cell Cell₁ is in the ruptured state, the read current of the first memory cell Cell₁ is larger, e.g., 2 mA. Whereas, if first memory cell Cell₁ is in the unruptured state, the read current of the first memory cell Cell₁ is very low (or nearly zero). Consequently, the storage state of the first memory cell Cell₁ can be determined according to the magnitude of the read current.

In the second memory cell Cell₂ (i.e., the unselected memory cell) of the array structure, the word line WL₂ receives the ground voltage (0V). Consequently, the select transistor M_{SEL2} and the switching transistor M_{SW2} are turned off. Under this circumstance, no read current is generated in the region between the antifuse transistor M_{AF2} and the bit line BL₁.

In the third memory cell Cell₃ (i.e., the unselected memory cell) of the array structure, the word line WL₁ receives the supply voltage V_{DD}, and the bit line BL₂ receives the supply voltage V_{DD}. Consequently, the select transistor M_{SEL3} and the switching transistor M_{SW3} are turned off. Under this circumstance, no read current is generated in the region between the antifuse transistor M_{AF1} and the bit line BL₂.

In the fourth memory cell Cell₄ (i.e., the unselected memory cell) of the array structure, the word line WL₂ receives the ground voltage (0V). Consequently, the select transistor M_{SEL4} and the switching transistor M_{SW4} are turned off. Under this circumstance, no read current is generated in the region between the antifuse transistor M_{AF2} and the bit line BL₂.

Moreover, when the read action (READ) is performed, the gate control line Gd receives the ground voltage (0V). Since the dummy transistors M_{DUMMY1}˜M_{DUMMY4} are ensured to be turned off, no leakage current will be generated.

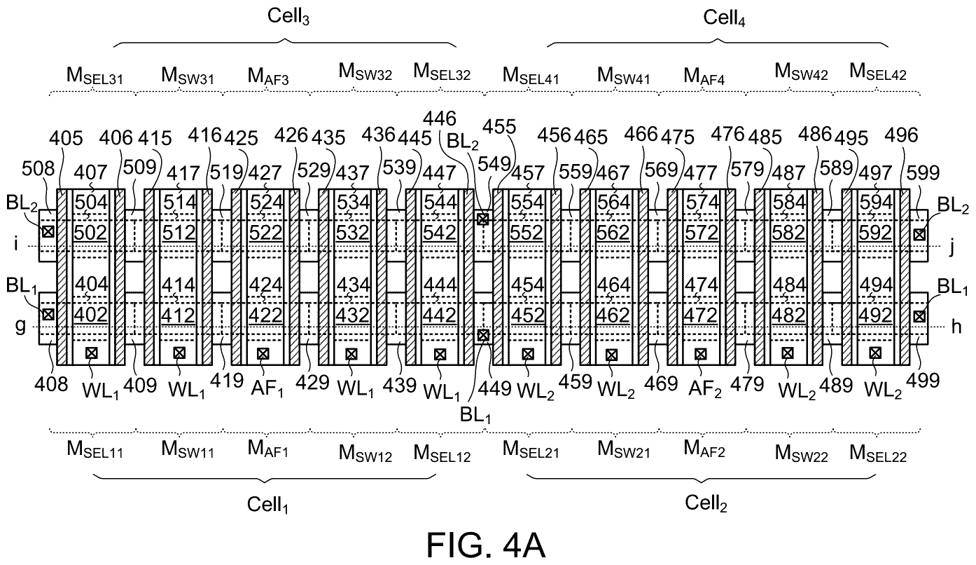

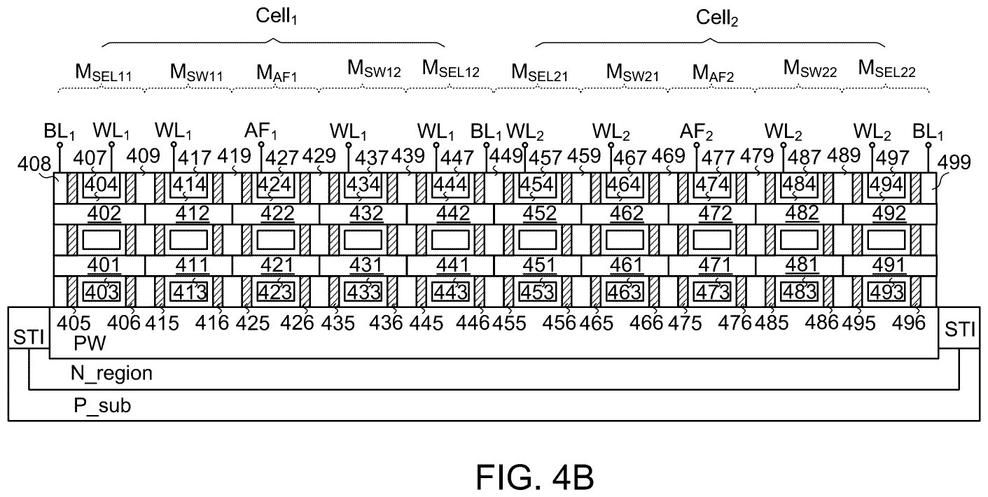

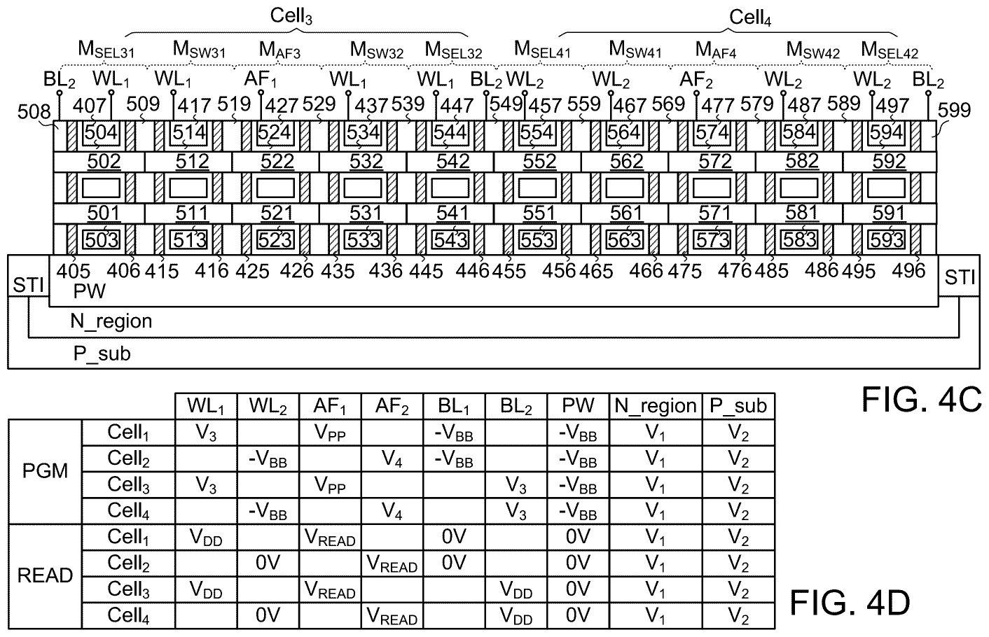

FIG. 4A is a schematic top view illustrating the array structure of an antifuse-type OTP memory according to a second embodiment of the present invention. FIG. 4B is a schematic cross-sectional view illustrating the array structure shown in FIG. 4A and taken along the line gh. FIG. 4C is a schematic cross-sectional view illustrating the array structure shown in FIG. 4A and taken along the line ij.

The array structure comprises four memory cells Cell₁˜Cell₄ in a 2×2 array. The structures of the four memory cells Cell₁˜Cell₄ are similar. Moreover, the array structure is constructed over a P-well region PW in a P-type semiconductor substrate P_sub. In addition, an N-type region N_region is formed in the P-type semiconductor substrate P_sub and located under the P-well region PW. For example, the N-type region N_region is a deep N-Well (DNW) region or an N-buried layer (NBL). The P-type semiconductor substrate P_sub and the P-well region PW are separated from each other through the N-type region N_region.

The array structure is at least connected with bit lines BL₁ and BL₂, word lines WL₁ and WL₂ and antifuse control lines AF₁ and AF₂. Each of the memory cells Cell₁˜Cell₄ in the array structure comprises at least five GAA transistors. The structure of each GAA transistor is the identical to the structure of the GAA transistor shown in FIG. 1A.

The first memory cell Cell₁ comprises a select transistor M_{SEL11}, a switching transistor M_{SW11}, an antifuse transistor M_{AF1}, a switching transistor M_{SW12} and a select transistor M_{SEL12}. The antifuse transistor M_{AF1} is used as a storage transistor.

The select transistor M_{SEL11} comprises a drain/source structure 408, a drain/source structure 409, a gate structure, a nanowire 401 and a nanowire 402. The gate structure comprises two spacers 405 and 406, two gate dielectric layers 403 and 404, and a gate layer 407. The gate dielectric layer 403 surrounds the central region of the nanowire 401. The gate dielectric layer 404 surrounds the central region of the nanowire 402. The gate layer 407 surrounds the gate dielectric layers 403 and 404. The first terminals of the nanowires 401 and 402 are surrounded by the spacer 405. The second terminals of the nanowires 401 and 402 are surrounded by the spacer 406. The nanowires 401 and 402 that are surrounded by the gate structure are served as a nanowire channel region of the select transistor M_{SEL11}. The drain/source structure 408 and the drain/source structure 409 are respectively located beside the two sides of the gate structure. The drain/source structure 408 is electrically contacted with the first terminals of the nanowires 401 and 402. The drain/source structure 409 is electrically contacted with the second terminals of the nanowires 401 and 402. The drain/source structure 408 is electrically contacted with the bit line BL₁. The gate layer 407 is electrically connected with the word line WL₁.

The switching transistor M_{SW11} comprises the drain/source structure 409, a drain/source structure 419, a gate structure, a nanowire 411 and a nanowire 412. The gate structure comprises two spacers 415 and 416, two gate dielectric layers 413 and 414, and a gate layer 417. The gate dielectric layer 413 surrounds the central region of the nanowire 411. The gate dielectric layer 414 surrounds the central region of the nanowire 412. The gate layer 417 surrounds the gate dielectric layers 413 and 414. The first terminals of the nanowires 411 and 412 are surrounded by the spacer 415. The second terminals of the nanowires 411 and 412 are surrounded by the spacer 416. The nanowires 411 and 412 that are surrounded by the gate structure are served as a nanowire channel region of the switching transistor M_{SW11}. The drain/source structure 409 and the drain/source structure 419 are respectively located beside the two sides of the gate structure. The drain/source structure 409 is electrically contacted with the first terminals of the nanowires 411 and 412. The drain/source structure 419 is electrically contacted with the second terminals of the nanowires 411 and 412. The gate layer 417 is electrically connected with the word line WL₁.

The antifuse transistor M_{AF1} comprises the drain/source structure 419, a drain/source structure 429, a gate structure, a nanowire 421 and a nanowire 422. The gate structure comprises two spacers 425 and 426, two gate dielectric layers 423 and 424, and a gate layer 427. The gate dielectric layer 423 surrounds the central region of the nanowire 421. The gate dielectric layer 424 surrounds the central region of the nanowire 422. The gate layer 427 surrounds the gate dielectric layers 423 and 424. The first terminals of the nanowires 421 and 422 are surrounded by the spacer 425. The second terminals of the nanowires 421 and 422 are surrounded by the spacer 426. The nanowires 421 and 422 that are surrounded by the gate structure are served as a nanowire channel region of the antifuse transistor M_{AF1}. The drain/source structure 419 and the drain/source structure 429 are respectively located beside the two sides of the gate structure. The drain/source structure 419 is electrically contacted with the first terminals of the nanowires 421 and 422. The drain/source structure 429 is electrically contacted with the second terminals of the nanowires 421 and 422. The gate layer 427 is electrically connected with the antifuse control line AF₁.

The switching transistor M_{SW12} comprises the drain/source structure 429, a drain/source structure 439, a gate structure, a nanowire 431 and a nanowire 432. The gate structure comprises two spacers 435 and 436, two gate dielectric layers 433 and 434, and a gate layer 437. The gate dielectric layer 433 surrounds the central region of the nanowire 431. The gate dielectric layer 434 surrounds the central region of the nanowire 432. The gate layer 437 surrounds the gate dielectric layers 433 and 434. The first terminals of the nanowires 431 and 432 are surrounded by the spacer 435. The second terminals of the nanowires 431 and 432 are surrounded by the spacer 436. The nanowires 431 and 432 that are surrounded by the gate structure are served as a nanowire channel region of the switching transistor M_{SW12}. The drain/source structure 429 and the drain/source structure 439 are respectively located beside the two sides of the gate structure. The drain/source structure 429 is electrically contacted with the first terminals of the nanowires 431 and 432. The drain/source structure 439 is electrically contacted with the second terminals of the nanowires 431 and 432. The gate layer 437 is electrically connected with the word line WL₁.

The select transistor M_{SEL12} comprises a drain/source structure 439, a drain/source structure 449, a gate structure, a nanowire 441 and a nanowire 442. The gate structure comprises two spacers 445 and 446, two gate dielectric layers 443 and 444, and a gate layer 447. The gate dielectric layer 443 surrounds the central region of the nanowire 441. The gate dielectric layer 444 surrounds the central region of the nanowire 442. The gate layer 447 surrounds the gate dielectric layers 443 and 444. The first terminals of the nanowires 441 and 442 are surrounded by the spacer 445. The second terminals of the nanowires 441 and 442 are surrounded by the spacer 446. The nanowires 441 and 442 that are surrounded by the gate structure are served as a nanowire channel region of the select transistor M_{SEL12}. The drain/source structure 439 and the drain/source structure 449 are respectively located beside the two sides of the gate structure. The drain/source structure 439 is electrically contacted with the first terminals of the nanowires 441 and 442. The drain/source structure 449 is electrically contacted with the second terminals of the nanowires 441 and 442. The drain/source structure 449 is electrically contacted with the bit line BL₁. The gate layer 447 is electrically connected with the word line WL₁.

In the first memory cell Cell₁, the drain/source structure 409 is shared by the select transistor M_{SEL11} and the switching transistor M_{SW11}, the drain/source structure 419 is shared by the switching transistor M_{SW11} and the antifuse transistor M_{AF1}, the drain/source structure 429 is shared by the antifuse transistor M_{AF1} and the switching transistor M_{SW12}, and the drain/source structure 439 is shared by the switching transistor M_{SW12} and the select transistor M_{SEL12}. In addition, the drain/source structures 408, 409, 419, 429, 439 and 449 and the nanowires 401, 402, 411, 412, 421, 422, 431, 432, 441 and 442 of the first memory cell Cell₁ have the same dopant type.

The second memory cell Cell₂ comprises a select transistor M_{SEL21}, a switching transistor M_{SW21}, an antifuse transistor M_{AF2}, a switching transistor M_{SW22} and a select transistor M_{SEL22}. The antifuse transistor M_{AF2} is used as a storage transistor.

The select transistor M_{SEL21} comprises the drain/source structure 449, a drain/source structure 459, a gate structure, a nanowire 451 and a nanowire 452. The gate structure comprises two spacers 455 and 456, two gate dielectric layers 453 and 454, and a gate layer 457. The gate layer 457 is electrically connected with the word line WL₂.

The switching transistor M_{SW21} comprises the drain/source structure 459, a drain/source structure 469, a gate structure, a nanowire 461 and a nanowire 462. The gate structure comprises two spacers 465 and 466, two gate dielectric layers 463 and 464, and a gate layer 467. The gate layer 467 is electrically connected with the word line WL₂.

The antifuse transistor M_{AF2} comprises the drain/source structure 469, a drain/source structure 479, a gate structure, a nanowire 471 and a nanowire 472. The gate structure comprises two spacers 475 and 476, two gate dielectric layers 473 and 474, and a gate layer 477. The gate layer 477 is electrically connected with the antifuse control line AF₂.

The switching transistor M_{SW22} comprises the drain/source structure 479, a drain/source structure 489, a gate structure, a nanowire 481 and a nanowire 482. The gate structure comprises two spacers 485 and 486, two gate dielectric layers 483 and 484, and a gate layer 487. The gate layer 487 is electrically connected with the word line WL₂.

The select transistor M_{SEL22} comprises the drain/source structure 489, a drain/source structure 499, a gate structure, a nanowire 491 and a nanowire 492. The gate structure comprises two spacers 495 and 496, two gate dielectric layers 493 and 494, and a gate layer 497. The drain/source structure 499 is electrically connected with the bit line BL₁. The gate layer 457 is electrically connected with the word line WL₂.

In the second memory cell Cell₂, the drain/source structure 459 is shared by the select transistor M_{SEL21} and the switching transistor M_{SW2}l, the drain/source structure 469 is shared by the switching transistor M_{SW21} and the antifuse transistor M_{AF2}, the drain/source structure 479 is shared by the antifuse transistor M_{AF2} and the switching transistor M_{SW22}, and the drain/source structure 489 is shared by the switching transistor M_{SW22} and the select transistor M_{SEL22}. In addition, the drain/source structures 449, 459, 469, 479, 489 and 499 and the nanowires 451, 452, 461, 462, 471, 472, 481, 482, 491 and 492 of the second memory cell Cell₂ have the same dopant type.

The third memory cell Cell₃ comprises a select transistor M_{SEL31}, a switching transistor M_{SW31}, an antifuse transistor M_{AF3}, a switching transistor M_{SW32} and a select transistor M_{SEL32}. The antifuse transistor M_{AF3} is used as a storage transistor.

The select transistor M_{SEL31} comprises a drain/source structure 508, a drain/source structure 509, a gate structure, a nanowire 501 and a nanowire 502. The gate structure comprises the two spacers 405 and 406, two gate dielectric layers 503 and 504, and the gate layer 407. In addition, the spacers 405 and 406 and the gate layer 407 are shared by the select transistor M_{SEL31} of the third memory cell Cell₃ and the select transistor M_{SEL11} of the first memory cell Cell₁.

The switching transistor M_{SW31} comprises the drain/source structure 509, a drain/source structure 519, a gate structure, a nanowire 511 and a nanowire 512. The gate structure comprises the two spacers 415 and 416, two gate dielectric layers 513 and 514, and the gate layer 417. In addition, the spacers 415 and 416 and the gate layer 417 are shared by the switching transistor M_{SW31} of the third memory cell Cell₃ and the switching transistor M_{SW11} of the first memory cell Cell₁.

The antifuse transistor M_{AF3} comprises the drain/source structure 519, a drain/source structure 529, a gate structure, a nanowire 521 and a nanowire 522. The gate structure comprises the two spacers 425 and 426, two gate dielectric layers 523 and 524, and the gate layer 427. In addition, the spacers 425 and 426 and the gate layer 427 are shared by the antifuse transistor M_{AF3} of the third memory cell Cell₃ and the antifuse transistor M_{AF1} of the first memory cell Cell₁.

The switching transistor M_{SW32} comprises the drain/source structure 529, a drain/source structure 539, a gate structure, a nanowire 531 and a nanowire 532. The gate structure comprises the two spacers 435 and 436, two gate dielectric layers 533 and 534, and the gate layer 437. In addition, the spacers 435 and 436 and the gate layer 437 are shared by the switching transistor M_{SW32} of the third memory cell Cell₃ and the switching transistor M_{SW12} of the first memory cell Cell₁.

The select transistor M_{SEL32} comprises a drain/source structure 539, a drain/source structure 549, a gate structure, a nanowire 541 and a nanowire 542. The gate structure comprises the two spacers 445 and 446, two gate dielectric layers 543 and 544, and the gate layer 447. In addition, the spacers 445 and 446 and the gate layer 447 are shared by the select transistor M_{SEL32} of the third memory cell Cell₃ and the select transistor M_{SEL12} of the first memory cell Cell₁.

In the third memory cell Cell₃, the drain/source structure 509 is shared by the select transistor M_{SEL31} and the switching transistor M_{SW3}l, the drain/source structure 519 is shared by the switching transistor M_{SW31} and the antifuse transistor M_{AF3}, the drain/source structure 529 is shared by the antifuse transistor M_{AF3} and the switching transistor M_{SW32}, and the drain/source structure 539 is shared by the switching transistor M_{SW32} and the select transistor M_{SEL32}. In addition, the drain/source structures 508, 509, 519, 529, 539 and 549 and the nanowires 501, 502, 511, 512, 521, 522, 531, 532, 541 and 542 of the third memory cell Cell₃ have the same dopant type.

The fourth memory cell Cell₄ comprises a select transistor M_{SEL41}, a switching transistor M_{SW41}, an antifuse transistor M_{AF4}, a switching transistor M_{SW42} and a select transistor M_{SEL42}. The antifuse transistor M_{AF4} is used as a storage transistor.

The select transistor M_{SEL41} comprises a drain/source structure 549, a drain/source structure 559, a gate structure, a nanowire 551 and a nanowire 552. The gate structure comprises the two spacers 455 and 456, two gate dielectric layers 553 and 554, and the gate layer 457. In addition, the spacers 445 and 446 and the gate layer 447 are shared by the select transistor M_{SEL41} of the fourth memory cell Cell₄ and the select transistor M_{SEL31} of the second memory cell Cell₂.

The switching transistor M_{SW41} comprises the drain/source structure 559, a drain/source structure 569, a gate structure, a nanowire 561 and a nanowire 562. The gate structure comprises the two spacers 465 and 466, two gate dielectric layers 563 and 564, and the gate layer 467. In addition, the spacers 465 and 466 and the gate layer 467 are shared by the switching transistor M_{SW41} of the fourth memory cell Cell₄ and the switching transistor M_{SW21} of the second memory cell Cell₂.

The antifuse transistor M_{AF4} comprises the drain/source structure 569, a drain/source structure 579, a gate structure, a nanowire 571 and a nanowire 572. The gate structure comprises the two spacers 475 and 476, two gate dielectric layers 573 and 574, and the gate layer 477. In addition, the spacers 475 and 476 and the gate layer 477 are shared by the antifuse transistor M_{AF4} of the fourth memory cell Cell₄ and the antifuse transistor M_{AF2} of the second memory cell Cell₂.

The switching transistor M_{SW42} comprises the drain/source structure 579, a drain/source structure 589, a gate structure, a nanowire 581 and a nanowire 582. The gate structure comprises the two spacers 485 and 486, two gate dielectric layers 583 and 584, and the gate layer 487. In addition, the spacers 485 and 486 and the gate layer 487 are shared by the switching transistor M_{SW42} of the fourth memory cell Cell₄ and the switching transistor M_{SW22} of the second memory cell Cell₂.

The select transistor M_{SEL42} comprises the drain/source structure 589, a drain/source structure 599, a gate structure, a nanowire 591 and a nanowire 592. The gate structure comprises the two spacers 495 and 496, two gate dielectric layers 593 and 594, and the gate layer 497. In addition, the spacers 495 and 496 and the gate layer 497 are shared by the select transistor M_{SEL42} of the fourth memory cell Cell₄ and the select transistor M_{SEL22} of the second memory cell Cell₂.

In the fourth memory cell Cell₄, the drain/source structure 559 is shared by the select transistor M_{SEL41} and the switching transistor M_{SW4}l, the drain/source structure 569 is shared by the switching transistor M_{SW41} and the antifuse transistor M_{AF4}, the drain/source structure 579 is shared by the antifuse transistor M_{AF4} and the switching transistor M_{SW42}, and the drain/source structure 589 is shared by the switching transistor M_{SW42} and the select transistor M_{SEL42}. In addition, the drain/source structures 549, 559, 569, 579, 589 and 599 and the nanowires 551, 552, 561, 562, 571, 572, 581, 582, 591 and 592 of the fourth memory cell Cell₄ have the same dopant type.

Similarly, in order to prevent the generation of a larger leakage current, the memory cells in the array structure of the antifuse-type OTP memory further comprises dummy transistors. For example, the four memory cells Cell₁˜Cell₄ comprise respective dummy transistors (not shown).

FIG. 4D is a table illustrating the bias voltages for performing a program action and a read action on the antifuse-type OTP memory of the second embodiment.

The processes and bias voltages for performing the program action (PGM) and the read action (READ) will be described as follows. For illustration, the first memory cell Cell₁ is a selected memory cell, and the other memory cells Cell₂˜Cell₄ are unselected memory cells.

When the array structure is subjected to the program action (PGM), the array structure receives a negative program voltage (−V_{BB}), the N-type region N_region receives a first voltage V₁, and the P-type semiconductor substrate P_sub receives a second voltage V₂. The negative program voltage (−V_{BB}) is lower than or equal to −1V, and the negative program voltage (−V_{BB}) is higher than or equal to −2.5V. The first voltage V₁ is higher than or equal to 0V, and the first voltage V₁ is lower than or equal to 1.6V. Moreover, the second voltage V₂ is higher than or equal to the negative program voltage (−V_{BB}), and the second voltage V₂ is lower than or equal to the first voltage V₁.

Please refer to FIG. 4D again. When the program action (PGM) is performed, the word line WL₁ receives a third voltage V₃, and the word line WL₂ receives the negative program voltage (−V_{BB}). Consequently, the word line WL₁ is a selected word line, and the word line WL₂ is an unselected word line. The third voltage V₃ may be regarded as an on voltage. The third voltage V₃ is higher than or equal to −1V, and the first voltage V₁ is lower than or equal to the supply voltage V_{DD}. In addition, the negative program voltage (−V_{BB}) may be regarded as an off voltage.

The bit line BL₁ receives the negative program voltage (−V_{BB}), and the bit line BL₂ receives the third voltage V₃. The antifuse control line AF₁ receives a positive program voltage V_{PP}, and the antifuse control line AF₂ receives a fourth voltage V₄. The positive program voltage V_{PP} is higher than or equal to 1V, and the positive program voltage V_{PP} is lower than or equal to 2.5V. The fourth voltage V₄ is higher than or equal to the negative program voltage (−V_{BB}), and the fourth voltage V₄ is lower than or equal to 0V.

In the first memory cell Cell₁ (i.e., the selected memory cell) of the array structure, the word line WL₁ receives the third voltage V₃. Consequently, the select transistor M_{SEL11}, the select transistor M_{SEL12}, the switching transistor M_{SW11} and the switching transistor M_{SW12} are turned on. The negative program voltage (−V_{BB}) is transmitted from the bit line BL₁ to the antifuse transistor M_{AF1} through the select transistor M_{SEL11}, the select transistor M_{SEL12}, the switching transistor M_{SW11} and the switching transistor M_{SW12}. Since the antifuse control line AF₁ receives the positive program voltage V_{PP}, the total voltage stress withstood by the two sides of the gate dielectric layers 423 and 424 of the antifuse transistor M_{AF1} is the total program voltage. That is, the total program voltage is approximately equal to the positive program voltage V_{PP} minus the negative program voltage (−V_{BB}), i.e., V_{PP}+V_{BB}. Consequently, one of the gate dielectric layers 423 and 424 is ruptured. Under this circumstance, the storage state of the first memory cell Cell₁ is changed from an unruptured state to a ruptured state.

In the second memory cell Cell₂ (i.e., the unselected memory cell) of the array structure, the word line WL₂ receives the negative program voltage (i.e., the off voltage). Consequently, the select transistor M_{SEL21}, the select transistor M_{SEL22}, the switching transistor M_{SW21} and the switching transistor M_{SW22} are turned off. Since no voltage stress is applied to the two sides of the gate dielectric layers 473 and 474 of the antifuse transistor M_{AF2}, both of the gate dielectric layers 473 and 474 are not ruptured. Under this circumstance, the storage state of the second memory cell Cell₂ is maintained in the unruptured state.

In the third memory cell Cell₃ (i.e., the unselected memory cell) of the array structure, the word line WL₁ receives the third voltage V₃, and the bit line BL₂ receives the third voltage V₃. Consequently, the select transistor M_{SEL31}, the select transistor M_{SEL32}, the switching transistor M_{SW31} and the switching transistor M_{SW32} are turned off. Since no voltage stress is applied to the two sides of the gate dielectric layers 523 and 524 of the antifuse transistor M_{AF3}, both of the gate dielectric layers 523 and 524 are not ruptured. Under this circumstance, the storage state of the third memory cell Cell₃ is maintained in the unruptured state.

In the fourth memory cell Cell₄ (i.e., the unselected memory cell) of the array structure, the word line WL₂ receives the negative program voltage (−V_{BB}), and the bit line BL₂ receives the third voltage V₃. Consequently, the select transistor M_{SEL41}, the select transistor M_{SEL42}, the switching transistor M_{SW41} and the switching transistor M_{SW42} are turned off. Since no voltage stress is applied to the two sides of the gate dielectric layers 573 and 574 of the antifuse transistor M_{AF4}, both of the gate dielectric layers 573 and 574 are not ruptured. Under this circumstance, the storage state of the fourth memory cell Cell₄ is maintained in the unruptured state.

When the array structure is subjected to the read action (READ), the P-well region PW receives the ground voltage (0V), the N-type region N_region receives the first voltage V₁, and the P-type semiconductor substrate P_sub receives the second voltage V₂.

Please refer to FIG. 4D again. When the read action (READ) is performed, the word line WL₁ receives the supply voltage V_{DD}, and the word line WL₂ receives the ground voltage (0V). Consequently, the word line WL₁ is the selected word line, and the word line WL₂ is the unselected word line. The supply voltage V_{DD} may be regarded as an on voltage. In addition, the ground voltage (0V) may be regarded as an off voltage.

The bit line BL₁ receives the ground voltage (0V), and the bit line BL₂ receives the supply voltage V_{DD}. The antifuse control line AF₁ receives a read voltage VREAD, and the antifuse control line AF₂ receives the read voltage VREAD. The read voltage VREAD is higher than or equal to 0.4V, and the read voltage VREAD is lower than or equal to 1.6V.

In the first memory cell Cell₁ (i.e., the selected memory cell) of the array structure, the word line WL₁ receives the supply voltage V_{DD}. Consequently, the select transistor M_{SEL11}, the select transistor M_{SEL12}, the switching transistor M_{SW11} and the switching transistor M_{SW12} are turned on. A read current is generated in the region between the antifuse transistor M_{AF1} and the bit line BL₁. The magnitude of the read current is related to the storage state of the first memory cell Cell₁. For example, if the first memory cell Cell₁ is in the ruptured state, the read current of the first memory cell Cell₁ is larger, e.g., 2 mA. Whereas, if first memory cell Cell₁ is in the unruptured state, the read current of the first memory cell Cell₁ is very low (or nearly zero). Consequently, the storage state of the first memory cell Cell₁ can be determined according to the magnitude of the read current.

In the second memory cell Cell₂ (i.e., the unselected memory cell) of the array structure, the word line WL₂ receives the ground voltage (0V). Consequently, the select transistor M_{SEL21}, the select transistor M_{SEL22}, the switching transistor M_{SW21} and the switching transistor M_{SW22} are turned off. Under this circumstance, no read current is generated in the region between the antifuse transistor M_{AF2} and the bit line BL₁.

In the third memory cell Cell₃ (i.e., the unselected memory cell) of the array structure, the word line WL₁ receives the supply voltage V_{DD}, and the bit line BL₂ receives the supply voltage V_{DD}. Consequently, the select transistor M_{SEL32}, the switching transistor M_{SW31} and the switching transistor M_{SW32} are turned off. Under this circumstance, no read current is generated in the region between the antifuse transistor M_{AF1} and the bit line BL₂.

In the fourth memory cell Cell₄ (i.e., the unselected memory cell) of the array structure, the word line WL₂ receives the ground voltage (0V). Consequently, the select transistor M_{SEL41}, the select transistor M_{SEL42}, the switching transistor M_{SW41} and the switching transistor M_{SW42} are turned off. Under this circumstance, no read current is generated in the region between the antifuse transistor M_{AF2} and the bit line BL₂.

In order to save the layout area of the antifuse-type OTP memory, the bias voltages provided to the array structure of the first embodiment or the array structure of the second embodiment may be varied. For example, in some other embodiments, the positive program voltage V_{PP} is replaced by the supply voltage V_{DD}. That is, when the program action is performed, the total program voltage is approximately equal to the supply voltage V_{DD} minus the negative program voltage (−V_{BB}), i.e., V_{DD}+V_{BB}. Under this circumstance, the gate dielectric layer of the antifuse transistor in the selected memory cell can be ruptured. Since the antifuse-type OTP memory is not equipped with a power circuit to generate the positive program voltage V_{PP}, the layout area of the antifuse-type OTP memory can be reduced.

Furthermore, the conducting lines in the array structure of the first embodiment or the array structure of the second embodiment may be varied according to the practical requirements.

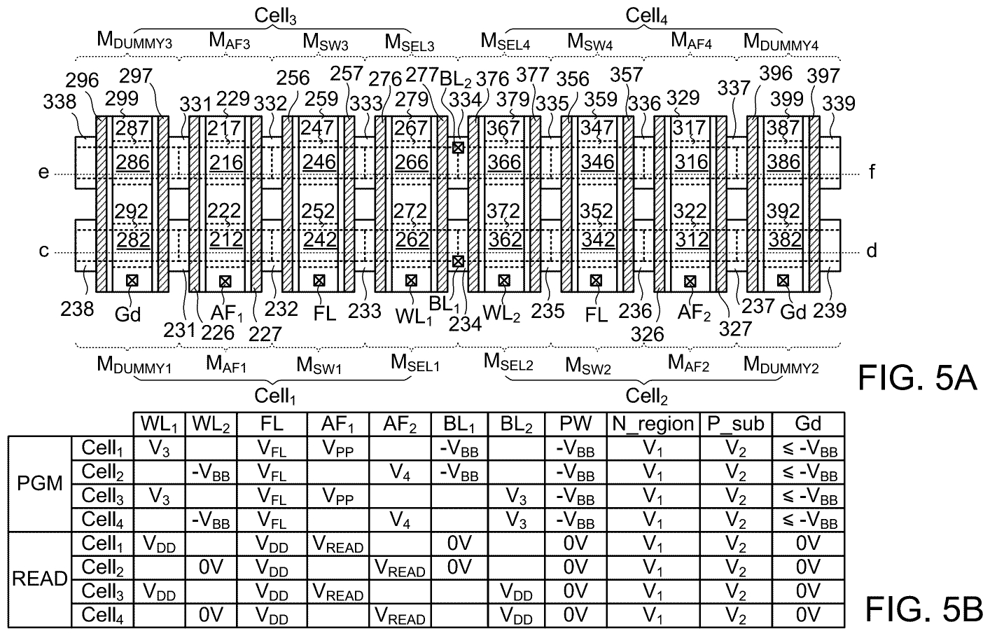

FIG. 5A is a schematic top view illustrating the array structure of an antifuse-type OTP memory according to a third embodiment of the present invention. FIG. 5B is a table illustrating the bias voltages for performing a program action and a read action on the antifuse-type OTP memory of the third embodiment. In comparison with the first embodiment, the switching transistors M_{SW1}, M_{SW3}, M_{SW2} and M_{SW4} in the array structure of the third embodiment are not connected with the corresponding word lines WL₁ and WL₂. For brevity, only the distinguished aspects between the third embodiment and the fourth embodiment will be described as follows.

Please refer to FIG. 5A. In the first memory cell Cell₁ and the third memory cell Cell₃, the conducting line connected with the gate layer 279 of the select transistor M_{SEL1} and the select transistor M_{SEL3} is severed as a word line WL₁, and the conducting line connected with the gate layer 259 of the switching transistor M_{SW1} and the switching transistor M_{SW3} is served as a following line FL. The word line WL₁ and the following line FL are not connected with each other. Similarly, in the second memory cell Cell₂ and the fourth memory cell Cell₄, the conducting line connected with the gate layer 379 of the select transistor M_{SEL2} and the select transistor M_{SEL4} is served as a word line WL₂, and the conducting line connected with the gate layer 359 of the switching transistor M_{SW2} and the switching transistor M_{SW4} is served as the following line FL. The word line WL₂ and the following line FL are not connected with each other. The conducting line connected with the gate layer 259 of the switching transistor M_{SW1} and the switching transistor M_{SW3} and the conducting line connected with the gate layer 359 of the switching transistor M_{SW2} and the switching transistor M_{SW4} are connected with each other and served as the following line FL.

Please refer to FIG. 5B. When the program action (PGM) is performed, the following line FL receives a following voltage V_{FL}. The following voltage V_{FL} is higher than or equal to 0V, and the following voltage V_{FL} is lower than or equal to 1.5V. In response to the following voltage V_{FL}, the switching transistors M_{SW1}, M_{SW3}, M_{SW2} and M_{SW4} can be maintained in the conducting state or the on state. Similarly, when the program action (PGM) is performed, the first memory cell Cell₁ is the selected memory cell, and the other memory cells Cell₂˜Cell₄ are the unselected memory cells. Consequently, the storage state of the first memory cell Cell₁ can be changed to the ruptured state, and the storage states of the memory cells Cell₂˜Cell₄ are kept unchanged.

Please refer to FIG. 5B again. When the read action (READ) is performed, the following line FL receives a supply voltage V_{DD}. In response to the supply voltage V_{DD}, the switching transistors M_{SW1}, M_{SW3}, M_{SW2} and M_{SW4} can be maintained in the conducting state or the on state. Similarly, when the read action (READ) is performed, the first memory cell Cell₁ generates a read current, but the memory cells Cell₂˜Cell₄ are unable to generate the read current.

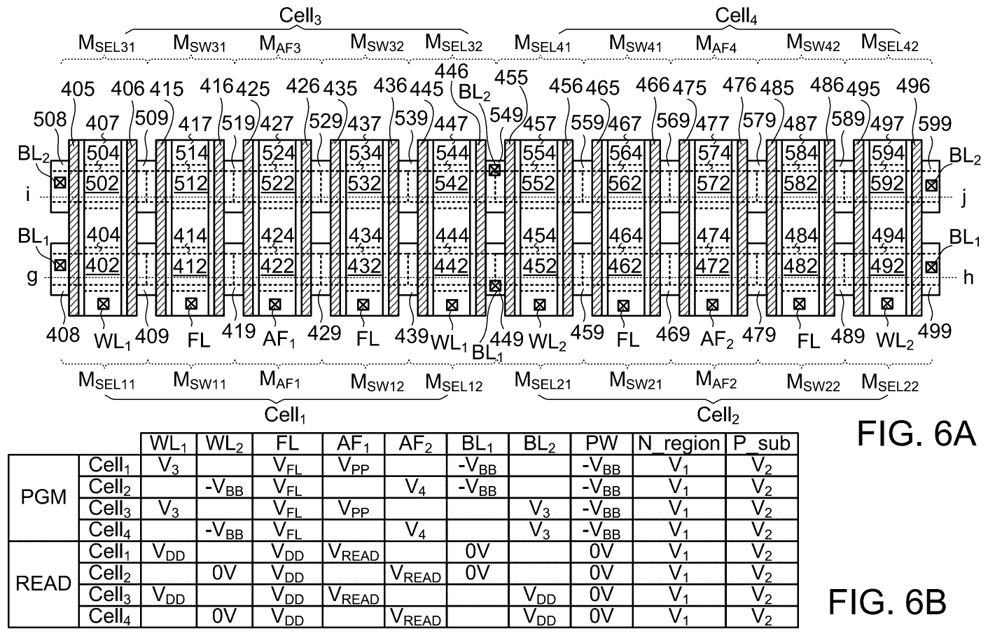

FIG. 6A is a schematic top view illustrating the array structure of an antifuse-type OTP memory according to a fourth embodiment of the present invention. FIG. 6B is a table illustrating the bias voltages for performing a program action and a read action on the antifuse-type OTP memory of the fourth embodiment. In comparison with the second embodiment, the switching transistors M_{SW1}, M_{SW3}, M_{SW2} and M_{SW4} in the array structure of the fourth embodiment are not connected with the corresponding word lines WL₁ and WL₂. For brevity, only the distinguished aspects between the fourth embodiment and the second embodiment will be described as follows.

Please refer to FIG. 6A. In the first memory cell Cell₁ and the third memory cell Cell₃, the conducting line connected with the gate layers 407 and 447 of the select transistors M_{SEL11}, M_{SEL12}, M_{SEL31} and M_{SEL32} is severed as a word line WL₁, and the conducting line connected with the gate layers 417 and 437 of the switching transistors M_{SW11}, M_{SW12}, M_{SW31} and M_{SW323} is served as a following line FL. The word line WL₁ and the following line FL are not connected with each other. Similarly, in the second memory cell Cell₂ and the fourth memory cell Cell₄, the conducting line connected with the gate layers 457 and 497 of the select transistors M_{SEL21}, M_{SEL22}, M_{SEL41} and M_{SEL42} is served as a word line WL₂, and the conducting line connected with the gate layers 467 and 487 of the switching transistors M_{SW21}, M_{SW22}, M_{SW41} and M_{SW42} is served as the following line FL. The word line WL₂ and the following line FL are not connected with each other. The conducting line connected with the gate layers 417 and 437 of the switching transistors M_{SW11}, M_{SW12}, M_{SW31} and M_{SW323} and the conducting line connected with the gate layers 467 and 487 of the switching transistors M_{SW21}, M_{SW22}, M_{SW41} and M_{SW42} are connected with each other and served as the following line FL.

Please refer to FIG. 6B. When the program action (PGM) is performed, the following line FL receives a following voltage V_{FL}. The following voltage V_{FL} is higher than or equal to 0V, and the following voltage V_{FL} is lower than or equal to 1.5V. In response to the following voltage V_{FL}, the switching transistors M_{SW1}, M_{SW3}, M_{SW2} and M_{SW4} can be maintained in the conducting state or the on state. Similarly, when the program action (PGM) is performed, the first memory cell Cell₁ is the selected memory cell, and the other memory cells Cell₂˜Cell₄ are the unselected memory cells. Consequently, the storage state of the first memory cell Cell₁ can be changed to the ruptured state, and the storage states of the memory cells Cell₂˜Cell₄ are kept unchanged.

Please refer to FIG. 6B again. When the read action (READ) is performed, the following line FL receives a supply voltage V_{DD}. In response to the supply voltage V_{DD}, the switching transistors M_{SW11}, M_{SW12}, M_{SW21}, M_{SW22}, M_{SW31}, M_{SW32}, M_{SW41} and M_{SW42} can be maintained in the conducting state or the on state. Similarly, when the read action (READ) is performed, the first memory cell Cell₁ generates a read current, but the memory cells Cell₂˜Cell₄ are unable to generate the read current.

From the above descriptions, the present invention an antifuse-type OTP memory and an associated bias voltage control method. When the program action (PGM) or the read action (READ) is performed, any memory cell of the array structure is determined as the selected memory cell, and the program action or the read action is performed on the selected memory cell. Furthermore, the positive program voltage V_{PP} and the negative program voltage (−V_{BB}) are combined as the total program voltage. Due to the voltage stress of the total program voltage, the gate dielectric layers of all GAA transistors in the antifuse-type OTP memory may be ruptured. Consequently, the program action can be performed successfully. Moreover, since the power circuits provide the negative program voltage (−V_{BB}) and the positive program voltage V_{PP}, all GAA transistors in the antifuse-type OTP memory can be normally operated in the safe operating area (SOA). In other words, the problem of causing the damage of the GAA transistors will be avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An antifuse-type one time programming memory comprising a first memory cell, the first memory cell comprising:
a P-type semiconductor substrate;
a P-type well region formed in a surface of the P-type semiconductor substrate;
an N-type region formed in the P-type semiconductor substrate and located under the P-type well region, wherein a region of the P-type semiconductor substrate underlying the N-type region and the P-type well region are separated from each other through the N-type region, and the P-type well region is formed as an isolated P-type well region;
a first nanowire;
a first gate structure comprising a first spacer, a second spacer, a first gate dielectric layer and a first gate layer, wherein the first gate dielectric layer surrounds a central region of the first nanowire, the first gate layer covers the first gate dielectric layer, the first gate layer is electrically connected with a first word line, a first terminal of the first nanowire is surrounded by the first spacer, a second terminal of the first nanowire is surrounded by the second spacer, and the first spacer and the second spacer are located over the P-type well region;
a first drain/source structure located over the P-type well region and electrically contacted with the first terminal of the first nanowire, wherein the first drain/source structure is electrically connected with a first bit line;
a second drain/source structure located over the P-type well region and electrically contacted with the second terminal of the first nanowire, wherein the first nanowire, the first gate structure, the first drain/source structure and the second drain/source structure are collaboratively formed as a first select transistor;
a second nanowire;
a second gate structure comprising a third spacer, a fourth spacer, a second gate dielectric layer and a second gate layer, wherein the second gate dielectric layer surrounds a central region of the second nanowire, the second gate layer covers the second gate dielectric layer, the second gate layer is electrically connected with a first antifuse control line, the first terminal of the second nanowire is surrounded by the third spacer, a second terminal of the second nanowire is surrounded by the fourth spacer, and the third spacer and the fourth spacer are located over the P-type well region;
a third drain/source structure located over the P-type well region and electrically contacted with the first terminal of the second nanowire, wherein the third drain/source structure is coupled to the second drain/source structure;
a fourth drain/source structure located over the P-type well region and electrically contacted with the second terminal of the second nanowire, wherein the second nanowire, the second gate structure, the third drain/source structure and the fourth drain/source structure are collaboratively formed as a first antifuse transistor;
wherein when a program action is performed, the P-type well region receives a negative program voltage, the N-type region receives a first voltage, and the P-type semiconductor substrate receives a second voltage, a region between the P-type well region and the N-type region is in a reverse bias condition, and a region between the P-type semiconductor substrate and the N-type region is in the reverse bias condition or a zero bias condition,
wherein the first voltage is higher than or equal to a ground voltage, the second voltage is higher than or equal to the negative program voltage, and the second voltage is lower than or equal to the first voltage.

2. The antifuse-type one time programming memory as claimed in claim 1, wherein the N-type region is a deep N-type well region or an N-type buried layer.

3. The antifuse-type one time programming memory as claimed in claim 1, wherein when a read action is performed, the P-type well region receives the ground voltage, the N-type region receives the first voltage, and the P-type semiconductor substrate receives the second voltage, the region between the P-type well region and the N-type region is in the reverse bias condition or the zero bias condition, and the region between the P-type semiconductor substrate and the N-type region is in the reverse bias condition or the zero bias condition.

4. The antifuse-type one time programming memory as claimed in claim 1, wherein the third drain/source structure is coupled to the second drain/source structure through a first switching transistor, and the first switching transistor comprises:
a third nanowire;
a third gate structure comprising a fifth spacer, a sixth spacer, a third gate dielectric layer and a third gate layer, wherein the third gate dielectric layer surrounds a central region of the third nanowire, the third gate layer covers the third gate dielectric layer, the third gate layer is electrically connected with a first conducting line, the first terminal of the third nanowire is surrounded by the fifth spacer, a second terminal of the third nanowire is surrounded by the sixth spacer, and the fifth spacer and the sixth spacer are located over the P-type well region;
the second drain/source structure electrically contacted with the first terminal of the third nanowire; and
the third drain/source structure electrically contacted with the second terminal of the third nanowire.

5. The antifuse-type one time programming memory as claimed in claim 1, wherein the first memory cell further comprise a dummy transistor, and the dummy transistor comprises:
a fourth nanowire;
a fourth gate structure comprising a seventh spacer, an eighth spacer, a fourth gate dielectric layer and a fourth gate layer, wherein the fourth gate dielectric layer surrounds a central region of the fourth nanowire, the fourth gate layer covers the fourth gate dielectric layer, the fourth gate layer is electrically connected with a dummy gate control line, a first terminal of the fourth nanowire is surrounded by the seventh spacer, a second terminal of the fourth nanowire is surrounded by the eighth spacer, and the seventh spacer and the eighth spacer are located over the P-type well region;
the fourth drain/source structure electrically contacted with the first terminal of the fourth nanowire; and
a fifth drain/source structure located over the P-type well region and electrically contacted with the second terminal of the fourth nanowire,
wherein when the program action is performed, the dummy gate control line receives a third voltage, and the third voltage is lower than or equal to the negative program voltage.

6. The antifuse-type one time programming memory as claimed in claim 4, wherein when the program action is performed, the first bit line receives the negative program voltage, and the first antifuse control line receives a positive program voltage, so that the first select transistor and the first switching transistor are turned on, wherein a total voltage stress withstood by two sides of the first gate dielectric layer of the first antifuse transistor is a total program voltage, and the total program voltage is approximately equal to the positive program voltage minus the negative program voltage, so that the first gate dielectric layer is ruptured, and a storage state of the first memory cell is changed from an unruptured state to a ruptured state.

7. The antifuse-type one time programming memory as claimed in claim 4, wherein the antifuse-type one time programming memory further comprises a second memory cell, and the second memory cell comprises:
a fourth nanowire, wherein a first terminal of the fourth nanowire is electrically contacted with the first drain/source structure;
a fourth gate structure comprising a seventh spacer, an eighth spacer, a fourth gate dielectric layer and a fourth gate layer, wherein the fourth gate dielectric layer surrounds a central region of the fourth nanowire, the fourth gate layer covers the fourth gate dielectric layer, the fourth gate layer is electrically connected with a second word line, the first terminal of the fourth nanowire is surrounded by the seventh spacer, a second terminal of the fourth nanowire is surrounded by the eighth spacer, and the seventh spacer and the eighth spacer are located over the P-type well region;
a fifth drain/source structure located over the P-type well region and electrically contacted with the second terminal of the fourth nanowire, wherein the fourth nanowire, the fourth gate structure, the first drain/source structure and the fifth drain/source structure are collaboratively formed as a second select transistor;
a fifth nanowire, wherein a first terminal of the fifth nanowire is electrically contacted with the fifth drain/source structure;
a fifth gate structure comprising a ninth spacer, a tenth spacer, a fifth gate dielectric layer and a fifth gate layer, wherein the fifth gate dielectric layer surrounds a central region of the fifth nanowire, the fifth gate layer covers the fifth gate dielectric layer, the fifth gate layer is electrically connected with a second conducting line, the first terminal of the fifth nanowire is surrounded by the ninth spacer, a second terminal of the fifth nanowire is surrounded by the tenth spacer, and the ninth spacer and the tenth spacer are located over the P-type well region;
a sixth drain/source structure located over the P-type well region and electrically contacted with the second terminal of the fifth nanowire, wherein the fifth nanowire, the fifth gate structure, the fifth drain/source structure and the sixth drain/source structure are collaboratively formed as a second switching transistor;
a sixth nanowire, wherein a first terminal of the sixth nanowire is electrically contacted with the sixth drain/source structure;
a sixth gate structure comprising an eleventh spacer, a twelfth spacer, a sixth gate dielectric layer and a sixth gate layer, wherein the sixth gate dielectric layer surrounds a central region of the sixth nanowire, the sixth gate layer covers the sixth gate dielectric layer, the sixth gate layer is electrically connected with a second antifuse control line, the first terminal of the sixth nanowire is surrounded by the eleventh spacer, a second terminal of the sixth nanowire is surrounded by the twelfth spacer, and the eleventh spacer and the twelfth spacer are located over the P-type well region; and
a seventh drain/source structure located over the P-type well region and electrically contacted with the second terminal of the sixth nanowire, wherein the sixth nanowire, the sixth gate structure, the sixth drain/source structure and the seventh drain/source structure are collaboratively formed as a second antifuse transistor.

8. The antifuse-type one time programming memory as claimed in claim 7, wherein the antifuse-type one time programming memory further comprises a third memory cell, and the third memory cell comprises:
a seventh nanowire;
a seventh gate structure comprising the first spacer, the second spacer, a seventh gate dielectric layer and the first gate layer, wherein the seventh gate dielectric layer surrounds a central region of the seventh nanowire, the first gate layer covers the seventh gate dielectric layer, a first terminal of the seventh nanowire is surrounded by the first spacer, and a second terminal of the seventh nanowire is surrounded by the second spacer;
an eighth drain/source structure located over the P-type well region and electrically contacted with the first terminal of the seventh nanowire, wherein the eighth drain/source structure is electrically connected with a second bit line;
a ninth drain/source structure located over the P-type well region and electrically contacted with the second terminal of the seventh nanowire, wherein the seventh nanowire, the seventh gate structure, the eighth drain/source structure and the ninth drain/source structure are collaboratively formed as a third select transistor;
an eighth nanowire, wherein a first terminal of the eighth nanowire is electrically contacted with the ninth drain/source structure;
an eighth gate structure comprising the fifth spacer, the sixth spacer, an eighth gate dielectric layer and the third gate layer, wherein the eighth gate dielectric layer surrounds a central region of the eighth nanowire, the third gate layer covers the eighth gate dielectric layer, the first terminal of the eighth nanowire is surrounded by the fifth spacer, and a second terminal of the eighth nanowire is surrounded by the sixth spacer;
a tenth drain/source structure located over the P-type well region and electrically contacted with the second terminal of the eighth nanowire, wherein the eighth nanowire, the eighth gate structure, the ninth drain/source structure and the tenth drain/source structure are collaboratively formed as a third switching transistor;
a ninth nanowire, wherein a first terminal of the ninth nanowire is electrically contacted with the tenth drain/source structure;
a ninth gate structure comprising the third spacer, the fourth spacer, a ninth gate dielectric layer and the second gate layer, wherein the ninth gate dielectric layer surrounds a central region of the ninth nanowire, the second gate layer covers the ninth gate dielectric layer, the first terminal of the ninth nanowire is surrounded by the third spacer, and a second terminal of the ninth nanowire is surrounded by the fourth spacer; and
an eleventh drain/source structure located over the P-type well region and electrically contacted with the second terminal of the ninth nanowire, wherein the ninth nanowire, the ninth gate structure, the tenth drain/source structure and the eleventh drain/source structure are collaboratively formed as a third antifuse transistor.

9. The antifuse-type one time programming memory as claimed in claim 7, wherein the first conducting line is connected with the first word line, and the second conducting line is connected with the second word line.

10. The antifuse-type one time programming memory as claimed in claim 9, wherein when the program action is performed, the first word line receives a third voltage, the second word line receives the negative program voltage, the first antifuse control line receives a positive program voltage, the second antifuse control line receives a fourth voltage, the first bit line receives the negative program voltage, and the second bit line receives the third voltage, wherein the third voltage is lower than or equal to a supply voltage and higher than or equal to −1V, the fourth voltage is higher than or equal to the negative program voltage and lower than or equal to the ground voltage, and when a read operation is performed, and the third memory cell is the unselected memory cell, the second bit line receives the supply voltage.

11. The antifuse-type one time programming memory as claimed in claim 7, wherein the first conducting line and the second conducting line are respectively used as a following line.

12. The antifuse-type one time programming memory as claimed in claim 11, wherein when the program action is performed, the first word line receives a third voltage, the second word line receives the negative program voltage, the first antifuse control line receives a positive program voltage, the second antifuse control line receives a fourth voltage, the first bit line receives the negative program voltage, the second bit line receives the third voltage, and the following line receives a following voltage, wherein the third voltage is lower than or equal to a supply voltage and higher than or equal to −1V, the fourth voltage is higher than or equal to the negative program voltage and lower than or equal to the ground voltage, and the supply voltage is higher than or equal to 0.4V and lower than or equal to 1.6V, and the following voltage is higher than or equal to the ground voltage and lower than or equal to 1.5V.

13. The antifuse-type one time programming memory as claimed in claim 4, wherein the first memory cell further comprises:
a fourth nanowire, wherein a first terminal of the fourth nanowire is electrically contacted with the fourth drain/source structure;
a fourth gate structure comprising a seventh spacer, an eighth spacer, a fourth gate dielectric layer and a fourth gate layer, wherein the fourth gate dielectric layer surrounds a central region of the fourth nanowire, the fourth gate layer covers the fourth gate dielectric layer, the fourth gate layer is electrically connected with the first conducting line, the first terminal of the fourth nanowire is surrounded by the seventh spacer, a second terminal of the fourth nanowire is surrounded by the eighth spacer, and the seventh spacer and the eighth spacer are located over the P-type well region;
a fifth drain/source structure located over the P-type well region and electrically contacted with the second terminal of the fourth nanowire, wherein the fourth nanowire, the fourth gate structure, the fourth drain/source structure and the fifth drain/source structure are collaboratively formed as a second switching transistor;
a fifth nanowire, wherein a first terminal of the fifth nanowire is electrically contacted with the fifth drain/source structure;
a fifth gate structure comprising a ninth spacer, a tenth spacer, a fifth gate dielectric layer and a fifth gate layer, wherein the fifth gate dielectric layer surrounds a central region of the fifth nanowire, the fifth gate layer covers the fifth gate dielectric layer, the fifth gate layer is electrically connected with the first word line, the first terminal of the fifth nanowire is surrounded by the ninth spacer, a second terminal of the fifth nanowire is surrounded by the tenth spacer, and the ninth spacer and the tenth spacer are located over the P-type well region;
a sixth drain/source structure located over the P-type well region and electrically contacted with the second terminal of the fifth nanowire, wherein the sixth drain/source structure is electrically connected with the first bit line, and wherein the fifth nanowire, the fifth gate structure, the fifth drain/source structure and the sixth drain/source structure are collaboratively formed as a second select transistor.

14. The antifuse-type one time programming memory as claimed in claim 13, wherein the antifuse-type one time programming memory further comprises a second memory cell, and the second memory cell comprises:
a sixth nanowire, wherein a first terminal of the sixth nanowire is electrically contacted with the first drain/source structure;
a sixth gate structure comprising an eleventh spacer, a twelfth spacer, a sixth gate dielectric layer and a sixth gate layer, wherein the sixth gate dielectric layer surrounds a central region of the sixth nanowire, the sixth gate layer covers the sixth gate dielectric layer, the sixth gate layer is electrically connected with a second word line, the first terminal of the sixth nanowire is surrounded by the eleventh spacer, a second terminal of the sixth nanowire is surrounded by the twelfth spacer, and the eleventh spacer and the twelfth spacer are located over the P-type well region;
a seventh drain/source structure located over the P-type well region and electrically contacted with the second terminal of the sixth nanowire, wherein the sixth nanowire, the sixth gate structure, the first drain/source structure and the seventh drain/source structure are collaboratively formed as a third select transistor;
a seventh nanowire, wherein a first terminal of the seventh nanowire is electrically contacted with the seventh drain/source structure;
a seventh gate structure comprising a thirteenth spacer, a fourteenth spacer, a seventh gate dielectric layer and a seventh gate layer, wherein the seventh gate dielectric layer surrounds a central region of the seventh nanowire, the seventh gate layer covers the seventh gate dielectric layer, the seventh gate layer is electrically connected with a second conducting line, a first terminal of the seventh nanowire is surrounded by the thirteenth spacer, a second terminal of the seventh nanowire is surrounded by the fourteenth spacer, and the thirteenth spacer and the fourteenth spacer are located over the P-type well region;
an eighth drain/source structure located over the P-type well region and electrically contacted with the second terminal of the seventh nanowire, wherein the seventh nanowire, the seventh gate structure, the seventh drain/source structure and the eighth drain/source structure are collaboratively formed as a third switching transistor;
an eighth nanowire, wherein a first terminal of the eighth nanowire is electrically contacted with the eighth drain/source structure;
an eighth gate structure comprising an fifteenth spacer, a sixteenth spacer, an eighth gate dielectric layer and an eighth gate layer, wherein the eighth gate dielectric layer surrounds a central region of the eighth nanowire, the eighth gate layer covers the eighth gate dielectric layer, the eighth gate layer is electrically connected with a second antifuse control line, the first terminal of the eighth nanowire is surrounded by the fifteenth spacer, a second terminal of the eighth nanowire is surrounded by the sixteenth spacer, and the fifteenth spacer and the sixteenth spacer are located over the P-type well region;
a ninth drain/source structure located over the P-type well region and electrically contacted with the second terminal of the eighth nanowire, wherein the eighth nanowire, the eighth gate structure, the eighth drain/source structure and the ninth drain/source structure are collaboratively formed as a second antifuse transistor;
a ninth nanowire, wherein a first terminal of the ninth nanowire is electrically contacted with the ninth drain/source structure;
a ninth gate structure comprising a seventeenth spacer, an eighteenth spacer, a ninth gate dielectric layer and a ninth gate layer, wherein the ninth gate dielectric layer surrounds a central region of the ninth nanowire, the ninth gate layer covers the ninth gate dielectric layer, the ninth gate layer is electrically connected with the second conducting line, the first terminal of the ninth nanowire is surrounded by the seventeenth spacer, a second terminal of the ninth nanowire is surrounded by the eighteenth spacer, and the seventeenth spacer and the eighteenth spacer are located over the P-type well region;
a tenth drain/source structure located over the P-type well region and electrically contacted with the second terminal of the ninth nanowire, wherein the ninth nanowire, the ninth gate structure, the ninth drain/source structure and the tenth drain/source structure are collaboratively formed as a fourth switching transistor;
a tenth nanowire, wherein a first terminal of the tenth nanowire is electrically contacted with the tenth drain/source structure;
a tenth gate structure comprising a nineteenth spacer, a twentieth spacer, a tenth gate dielectric layer and a tenth gate layer, wherein the tenth gate dielectric layer surrounds a central region of the tenth nanowire, the tenth gate layer covers the tenth gate dielectric layer, the tenth gate layer is electrically connected with the second word line, a first terminal of the tenth nanowire is surrounded by the nineteenth spacer, a second terminal of the tenth nanowire is surrounded by the twentieth spacer, and the nineteenth spacer and the twentieth spacer are located over the P-type well region; and
an eleventh drain/source structure located over the P-type well region and electrically contacted with the second terminal of the tenth nanowire, wherein the eleventh drain/source structure is electrically connected with the first bit line, and wherein the tenth nanowire, the tenth gate structure, the tenth drain/source structure and the eleventh drain/source structure are collaboratively formed as a fourth select transistor.

15. The antifuse-type one time programming memory as claimed in claim 14, wherein the antifuse-type one time programming memory further comprises a third memory cell, and the third memory cell comprises:
an eleventh nanowire;
an eleventh gate structure comprising the first spacer, the second spacer, an eleventh gate dielectric layer and the first gate layer, wherein the eleventh gate dielectric layer surrounds a central region of the eleventh nanowire, the first gate layer covers the eleventh gate dielectric layer, a first terminal of the eleventh nanowire is surrounded by the first spacer, and a second terminal of the eleventh nanowire is surrounded by the second spacer;
a twelfth drain/source structure located over the P-type well region and electrically contacted with the first terminal of the eleventh nanowire, wherein the twelfth drain/source structure is electrically connected with a second bit line;
a thirteenth drain/source structure located over the P-type well region and electrically contacted with the second terminal of the eleventh nanowire, wherein the eleventh nanowire, the eleventh gate structure, the twelfth drain/source structure and the thirteenth drain/source structure are collaboratively formed as a fifth select transistor;
a twelfth nanowire, wherein a first terminal of the twelfth nanowire is electrically contacted with the thirteenth drain/source structure;
a twelfth gate structure comprising the fifth spacer, the sixth spacer, a twelfth gate dielectric layer and the third gate layer, wherein the twelfth gate dielectric layer surrounds a central region of the twelfth nanowire, the third gate layer covers the twelfth gate dielectric layer, the first terminal of the twelfth nanowire is surrounded by the fifth spacer, and a second terminal of the twelfth nanowire is surrounded by the sixth spacer;
a fourteenth drain/source structure located over the P-type well region and electrically contacted with the second terminal of the twelfth nanowire, wherein the twelfth nanowire, the twelfth gate structure, the thirteenth drain/source structure and the fourteenth drain/source structure are collaboratively formed as a fifth switching transistor;
a thirteenth nanowire, wherein a first terminal of the thirteenth nanowire is electrically contacted with the fourteenth drain/source structure;
a thirteenth gate structure comprising the third spacer, the fourth spacer, a thirteenth gate dielectric layer and the second gate layer, wherein the thirteenth gate dielectric layer surrounds a central region of the thirteenth nanowire, the second gate layer covers the thirteenth gate dielectric layer, the first terminal of the thirteenth nanowire is surrounded by the third spacer, and a second terminal of the thirteenth nanowire is surrounded by the fourth spacer;
a fifteenth drain/source structure located over the P-type well region and electrically contacted with the second terminal of the thirteenth nanowire, wherein the thirteenth nanowire, the thirteenth gate structure, the fourteenth drain/source structure and the fifteenth drain/source structure are collaboratively formed as a third antifuse transistor;
a fourteenth nanowire, wherein a first terminal of the fourteenth nanowire is electrically contacted with the fifteenth drain/source structure;
a fourteenth gate structure comprising the seventh spacer, the eighth spacer, a fourteenth gate dielectric layer and the fourth gate layer, wherein the fourteenth gate dielectric layer surrounds a central region of the fourteenth nanowire, the fourth gate layer covers the fourteenth gate dielectric layer, a first terminal of the fourteenth nanowire is surrounded by the seventh spacer, and a second terminal of the fourteenth nanowire is surrounded by the eighth spacer;
a sixteenth drain/source structure located over the P-type well region and electrically contacted with the second terminal of the fourteenth nanowire, wherein the fourteenth nanowire, the fourteenth gate structure, the fifteenth drain/source structure and the sixteenth drain/source structure are collaboratively formed as a sixth switching transistor;
a fifteenth nanowire, wherein a first terminal of the fifteenth nanowire is electrically contacted with the sixteenth drain/source structure;
a fifteenth gate structure comprising the ninth spacer, the tenth spacer, a fifteenth gate dielectric layer and the fifth gate layer, wherein the fifteenth gate dielectric layer surrounds a central region of the fifteenth nanowire, the fifth gate layer covers the fifteenth gate dielectric layer, a first terminal of the fifteenth nanowire is surrounded by the ninth spacer, and a second terminal of the fifteenth nanowire is surrounded by the tenth spacer; and
a seventeenth drain/source structure located over the P-type well region and electrically contacted with the second terminal of the fifteenth nanowire, wherein the seventeenth drain/source structure is electrically connected with the second bit line, and wherein the fifteenth nanowire, the fifteenth gate structure, the sixteenth drain/source structure and the seventeenth drain/source structure are collaboratively formed as a sixth select transistor.

16. The antifuse-type one time programming memory as claimed in claim 15, wherein the first conducting line is connected with the first word line, and the second conducting line is connected with the second word line.

17. The antifuse-type one time programming memory as claimed in claim 16, wherein when the program action is performed, the first word line receives a third voltage, the second word line receives the negative program voltage, the first antifuse control line receives a positive program voltage, the second antifuse control line receives a fourth voltage, the first bit line receives the negative program voltage, and the second bit line receives the third voltage, wherein the third voltage is lower than or equal to a supply voltage and higher than or equal to −1V, the fourth voltage is higher than or equal to the negative program voltage and lower than or equal to the ground voltage, and the supply voltage is higher than or equal to 0.4V and lower than or equal to 1.6V.

18. The antifuse-type one time programming memory as claimed in claim 15, wherein the first conducting line and the second conducting line are respectively used as a following line.

19. The antifuse-type one time programming memory as claimed in claim 18, wherein when the program action is performed, the first word line receives a third voltage, the second word line receives the negative program voltage, the first antifuse control line receives a positive program voltage, the second antifuse control line receives a fourth voltage, the first bit line receives the negative program voltage, the second bit line receives the third voltage, and the following line receives a following voltage, wherein the third voltage is lower than or equal to a supply voltage and higher than or equal to −1V, the fourth voltage is higher than or equal to the negative program voltage and lower than or equal to the ground voltage, and the supply voltage is higher than or equal to 0.4V and lower than or equal to 1.6V, and the following voltage is higher than or equal to the ground voltage and lower than or equal to 1.5V.
